(19) United States
(12) Patent Application Publication
(10) Pub. No.: US 2025/0234622 A1
(43) Pub. Date: Jul. 17, 2025

(54) NANOSTRUCTURE DEVICE WITH REDUCED HIGH-K DIELECTRIC AREA AND RELATED METHOD

(71) Applicant: Taiwan Semiconductor Manufacturing Co., Ltd., Hsinchu (TW)

(72) Inventors: Chung-Wei HSU, Hsinchu (TW); Lung-Kun CHU, Hsinchu (TW); Shih-Hao LAI, Hsinchu (TW); Yi-Bo LIAO, Hsinchu (TW); Kuo-Cheng CHIANG, Hsinchu (TW); Chih-Hao WANG, Hsinchu (TW)

(21) Appl. No.: 18/777,240

(22) Filed: Jul. 18, 2024

Related U.S. Application Data
(60) Provisional application No. 63/621,460, filed on Jan. 16, 2024.

(51) Int. Cl. H01L 29/423; H01L 21/28; H01L 29/06; H01L 29/40; H01L 29/51; H01L 29/66; H01L 29/775; H01L 29/786

(52) U.S. Cl. CPC H10D 64/516; H01L 21/28008; H10D 64/01; H10D 64/015; H10D 64/685; H10D 30/014; H10D 30/43; H10D 30/6735; H10D 30/6757; H10D 62/121; H10D 64/017

(57) ABSTRACT

A semiconductor device includes a stack of nanostructures, a first layer over and offset from the stack of nanostructures, an inner spacer between the first layer and the stack of nanostructures, and a gate structure wrapping around the stack of nanostructures. The gate structure includes a gate dielectric on the nanostructures and between the inner spacer and the nanostructures of the stack of nanostructures and a gate metal on the gate dielectric.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B are diagrammatic cross-sectional side views of a portion of a semiconductor device according to embodiments of the present disclosure.

FIGS. 2A-18 are views of various embodiments of a semiconductor structure of at various stages of fabrication according to various aspects of the present disclosure.

FIG. 19 is a flowchart of a method of forming an IC device in accordance with various embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Terms indicative of relative degree, such as “about,” “substantially,” and the like, should be interpreted as one having ordinary skill in the art would in view of current technological norms.

The terms “first,” “second,” “third” and so on may be used herein to describe a sequence of events or sequential order of elements but may be exchanged or varied in some contexts. For example, a second layer may be formed on (e.g., sequentially after) a first layer, but in some contexts the first layer may be referred to as a “second layer,” “third layer,” “fourth layer” or the like, and the second layer may be referred to as a “first layer,” “third layer,” “fourth layer,” or the like.

The term “surrounds” may be used herein to describe a structure that fully or partially encloses another element or structure, for example, in three dimensions. For example, a first structure may “surround” a second structure on four lateral sides (e.g., left, right, front and back) without surrounding the second structure on two vertical sides (e.g., top and bottom). In other example, the first structure may wrap partially around the second structure, for example, by wrapping around three sides (e.g., top, front and back) while leaving other sides (e.g., left, right and bottom) exposed.

Source/drain region(s) may refer to a source region or structure or a drain region or structure, individually or collectively dependent upon the context.

The present disclosure is generally related to semiconductor devices, and more particularly to field-effect transistors (FETs), such as planar FETs, three-dimensional fin FETs (FinFETs), or nanostructure FETs, such as nanosheet FETs (NSFETs), nanowire FETs (NWFETs), gate-all-around FETs (GAAFETs) and the like.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

Embodiments of the disclosure include a gate-protection top (GPT) hard mask or “dielectric protective layer” that can aid in selectively removing some of the high-k dielectric material from the low-k dielectric spacers. By reducing the amount of high-k dielectric material on the low-k dielectric spacers, embodiments of the disclosure reduce parasitic capacitance and improve device performance. Reliability is improved by increasing distance between source/drain contacts and gate contacts via thicker low-k dielectric spacers that replace the HK material at the sidewalls.

The nanostructure transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the nanostructure structure.

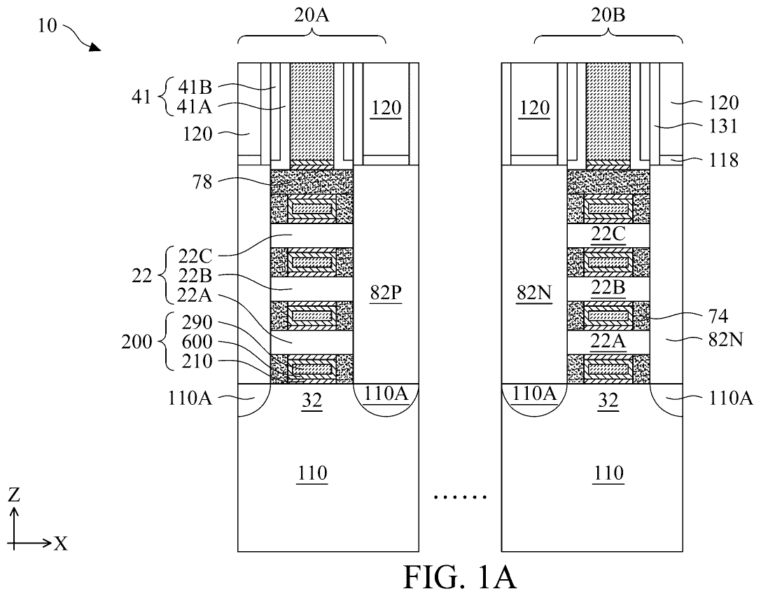

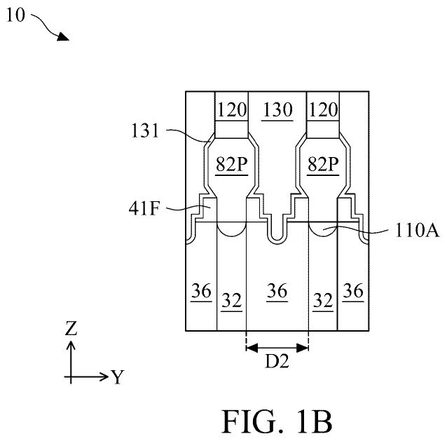

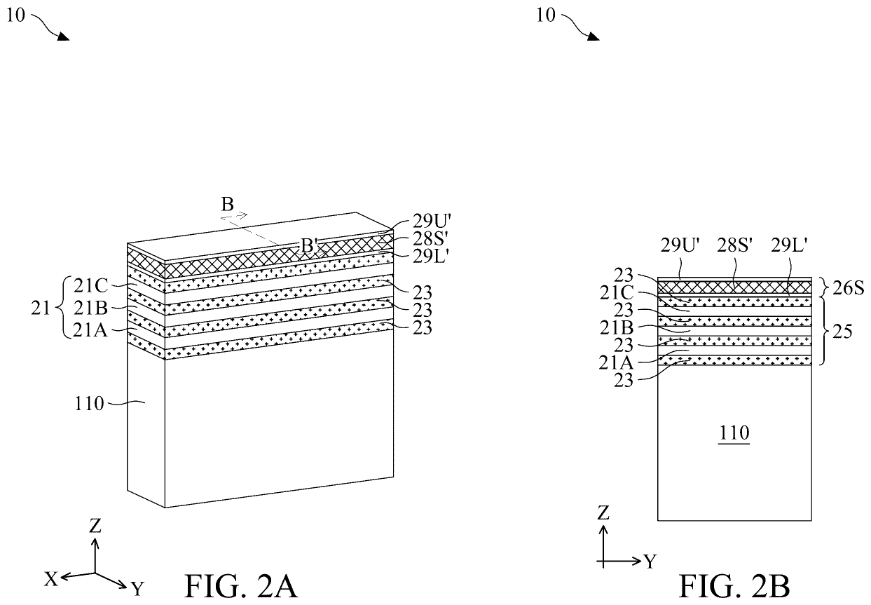

FIGS. 1A and 1B are diagrammatic cross-sectional side views of a portion of a nanostructure device 10 in accordance with various embodiments. FIG. 1A illustrates a view in an X-Z plane. FIG. 1B illustrates a view in a Y-Z plane orthogonal to the X-Z plane. The nanostructure device 10 of FIGS. 1A, 1B is described in detail below to provide context for understanding the technical features and benefits of the various embodiments depicted in FIGS. 2A-18.

Referring to FIG. 1A, nanostructure devices 20A, 20B may be or include one or more N-type FETs (NFETs) or P-type FETs (PFETs). For example, the nanostructure device 20A may be a PFET and the nanostructure device 20B may be an NFET. The nanostructure devices 20A, 20B are formed over and/or in a substrate 110, and generally include gate structures 200 straddling and/or wrapping around semiconductor channels 22A, 22B, 22C, alternately referred to as “nanostructures,” located over semiconductor fins 32 protruding from, and separated by, isolation structures 36 (see FIG. 1B). The semiconductor channels 22A, 22B, 22C may be referred to collectively as channels 22. The gate structure 200 controls electrical current flow through the channels 22A, 22B, 22C between source/drains 82N, 82P on either side thereof.

The nanostructure devices 20A, 20B are shown including three channels 22A, 22B, 22C, which are laterally abutted by source/drain features 82N, 82P, and covered and surrounded by the gate structure 200. Generally, the number of channels 22 is two or more, such as three or four or more, but may be one in some embodiments. The gate structure 200 controls flow of electrical current through the channels 22A, 22B, 22C to and from the source/drain features 82N, 82P based on voltages applied at the gate structure 200 and at the source/drain features 82N, 82P.

In some embodiments, the fin structure 32 includes silicon. In some embodiments, the nanostructure device 20B includes an NFET, and the source/drain features 82N thereof include silicon phosphorous (SiP), SiAs, SiSb, SiPAs, SiP:As:Sb, SiGe, combinations thereof, or the like. In some embodiments, the nanostructure device 20A includes a PFET, and the source/drain features 82P thereof include silicon germanium (SiGe), either undoped or doped to form, for example, SiGe:B, SiGe:B:Ga, SiGe:Sn, SiGe:B:Sn, or another appropriate semiconductor material. Generally, the source/drain features 82N, 82P may include any combination of appropriate semiconductor material(s) and appropriate dopant(s). As depicted in FIG. 1B, adjacent fins 32 may be separated by a distance D2 that is in a range of about 20 nm to about 60 nm.

The channels 22A, 22B, 22C each include a semiconductive material, for example silicon or germanium or a semiconductor alloy, such as SiGe, GeSn, SiGeSn, GaAs, InGaAs, one or more two-dimensional materials with semiconducting properties, such as MoS₂, WS₂, combinations thereof, and the like. The channels 22A, 22B, 22C are nanostructures (e.g., having at least one dimension that is in a range of a few nanometers) and may also each have an elongated shape and extend in the X-direction. In some embodiments, the channels 22A, 22B, 22C each have a nanowire (NW) shape, a nanosheet (NS) shape, a nanotube (NT) shape, or other suitable nanoscale shape. The cross-sectional profile of the channels 22A, 22B, 22C may be rectangular, round, square, circular, elliptical, hexagonal, or combinations thereof.

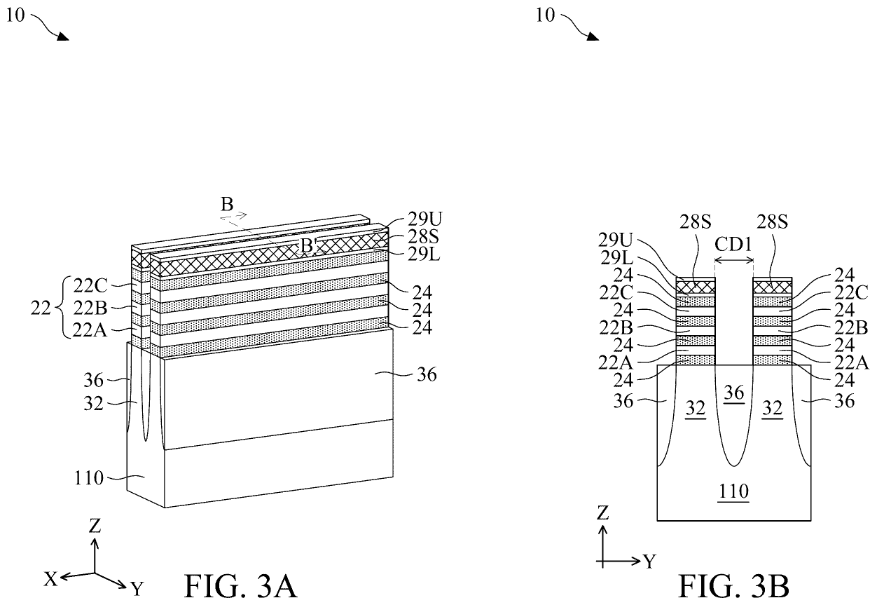

In some embodiments, the lengths (e.g., measured in the X-direction) of the channels 22A, 22B, 22C may be different from each other, for example due to tapering during a fin etching process (see FIGS. 3A, 3B). In some embodiments, length of the channel 22C may be less than a length of the channel 22B, which may be less than a length of channel 22A. The channels 22A, 22B, 22C each may not have uniform thickness (e.g., along the X-axis direction), for example due to a channel trimming process used to expand spacing (e.g., measured in the Z-axis direction) between the channels 22A, 22B, 22C to increase gate structure fabrication process window. For example, a middle portion of each of the channels 22A, 22B, 22C may be thinner than the two ends of each of the channels 22A, 22B, 22C. Such shape may be collectively referred to as a “dog-bone” shape.

In some embodiments, the spacing between the channels 22A, 22B, 22C (e.g., between the channel 22B and the channel 22A or the channel 22C) is in a range between about 5.5 nanometers (nm) and about 15 nm, though ranges exceeding or below the said range may also be beneficial. In some embodiments, a thickness (e.g., measured in the Z-direction) of each of the channels 22A, 22B, 22C is in a range between about 1 nm and about 10 nm, though ranges exceeding or below the said range may also be beneficial. In some embodiments, a width (e.g., measured in the Y-direction, shown in FIG. 3B, orthogonal to the X-Z plane) of each of the channels 22A, 22B, 22C is at least about 8 nm, however the width may be less than 8 nm in some embodiments.

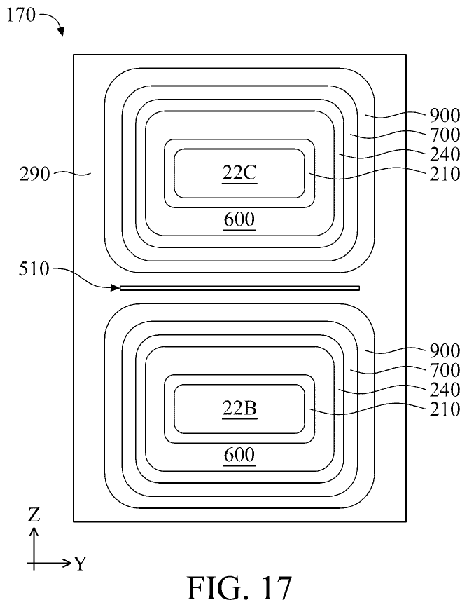

The gate structure 200 is disposed over and between the channels 22A, 22B, 22C, respectively. In some embodiments, the gate structure 200 is disposed over and between the channels 22A, 22B, 22C, which are silicon channels for N-type devices or silicon germanium channels for P-type devices. In some embodiments, the gate structure 200 includes an interfacial layer (IL) 210, one or more gate dielectric layers 600 on the interfacial layer 210 and a metal core layer 290 on the gate dielectric layer 600. Additional layers, such as one or more work function tuning layers 900 (see FIG. 17) may be present on the gate dielectric layer 600 between the gate dielectric layer 600 and the metal core layer 290.

The interfacial layer 210, which may be an oxide of the material of the channels 22A, 22B, 22C, is formed on exposed areas of the channels 22A, 22B, 22C and the top surface of the fin 32. The interfacial layer 210 promotes adhesion of the gate dielectric layers 600 to the channels 22A, 22B, 22C. In some embodiments, the interfacial layer 210 has thickness of about 5 Angstroms (A) to about 50 Angstroms (A). In some embodiments, the interfacial layer 210 has thickness of about 10 A. The interfacial layer 210 having thickness that is too thin may exhibit voids or insufficient adhesion properties. The interfacial layer 210 being too thick consumes gate fill window, which is related to threshold voltage tuning and resistance. In some embodiments, the interfacial layer 210 is doped with a dipole, such as lanthanum, for threshold voltage tuning.

In some embodiments, the gate dielectric layer 600 includes at least one high-k gate dielectric material, which may refer to dielectric materials having a high dielectric constant that is greater than a dielectric constant of silicon oxide (k≈3.9). Example high-k dielectric materials include HfO₂, HfSiO, HfSiON, HfTaO, HfTiO, HfZrO, ZrO₂, Ta₂O₅, or combinations thereof. In some embodiments, the gate dielectric layer 600 has thickness of about 5 A to about 100 A. The gate dielectric layer 600 may be a single layer or a multilayer.

The gate structure 200 also includes metal core layer 290. The metal core layer 290 may include a conductive material such as Co, W, Ru, combinations thereof, or the like. In some embodiments, the metal core layer 290 is or includes a Co-, W- or Ru-based compound or alloy including one or more elements, such as Zr, Sn, Ag, Cu, Au, Al, Ca, Be, Mg, Rh, Na, Ir, W, Mo, Zn, Ni, K, Co, Cd, Ru, In, Os, Si, Ge, Mn, combinations thereof, or the like. Between the channels 22A, 22B, 22C, the metal core layer 290 is circumferentially surrounded (in the cross-sectional view) by the one or more work function metal layers 900, which are then circumferentially surrounded by the gate dielectric layers 600, which are circumferentially surrounded by the interfacial layer 210.

As depicted in FIG. 1A, the nanostructure devices 20A, 20B may further include source/drain contacts 120 that are formed over the source/drain features 82N, 82P. The source/drain contacts 120 may include a core layer that is or includes a conductive material such as tungsten, ruthenium, cobalt, copper, titanium, titanium nitride, tantalum, tantalum nitride, iridium, molybdenum, nickel, aluminum, or combinations thereof. The core layer may be surrounded by one or more liner (or, “barrier”) layers, such as SiN or TiN, which help prevent or reduce diffusion of materials from and into the source/drain contacts 120. In some embodiments, height of the source/drain contacts 120 may be in a range of about 1 nm to about 50 nm.

Silicide layers 118 may be positioned between the source/drain features 82N, 82P and the source/drain contacts 120, at least to reduce the source/drain contact resistance. In some embodiments, the silicide layer 118 is or includes TiSi, CrSi, TaSi, MoSi, ZrSi, HfSi, ScSi, YSi, HoSi, TbSi, GdSi, LuSi, DySi, ErSi, YbSi, or the like. In some embodiments, the silicide layer 118 is or includes NiSi, CoSi, MnSi, WSi, FeSi, RhSi, PdSi, RuSi, PtSi, IrSi, OsSi, or the like. The silicide layer 118 may have thickness in a range of about 1 nm to about 10 nm. Thickness lower than about 1 nm may lead to an insufficient reduction in contact resistance. Thickness above about 10 nm may cause electrical shorting with the nanostructures 22. In some embodiments, the silicide layer 118 is present below, and in contact with, etch stop layer 131.

As depicted in FIG. 1B, the nanostructure devices 20A, 20B may further include an interlayer dielectric (ILD) 130. The ILD 130 provides electrical isolation between the various components of the nanostructure devices 20A, 20B discussed above, for example between neighboring pairs of the source/drain contacts 120 and/or the source/drains 82P (or the source/drains 82N). An etch stop layer 131 may be formed prior to forming the ILD 130 and may be positioned laterally between the ILD 130 and the gate spacers 41 and vertically between the ILD 130 and the source/drain features 82N, 82P. In some embodiments, the etch stop layer 131 is or includes SiN, SiCN, SiC, SiOC, SiOCN, HfO₂, ZrO₂, ZrAlOx, HfAlOx, HfSiOx, Al₂O₃, or other suitable material. In some embodiments, thickness of the etch stop layer is in a range of about 1 nm to about 5 nm. In some embodiments, where the ILD 130 is not present (e.g., is removed completely prior to formation of the source/drain contacts 120), the etch stop layer 131 may be in contact with the source/drain contact 120. The etch stop layer 131 may be trimmed, for example, in the X-axis direction prior to formation of the source/drain contact 120 to improve fill quality of the source/drain contact 120.

The nanostructure devices 20A, 20B include gate spacers 41 that are disposed on sidewalls of the metal core layer 290 above the channel 22C, and inner spacers 74 that are disposed on sidewalls of the IL 210 and/or the gate dielectric layer 600 between the channels 22A, 22B, 22C. The inner spacers 74 are also disposed between the channels 22A, 22B, 22C. In the embodiment depicted in FIG. 1A, the gate spacers 41 include a first spacer layer 41A and a second spacer layer 41B on the first spacer layer 41A. The first and second spacer layers 41A, 41B may each include a dielectric material, for example a low-k material such as SiOCN, SiON, SiN, SiCN, SiOC or the like. In some embodiments, the second spacer layer 41B is not present. Material of the first and second spacer layers 41A, 41B may be the same as or different from each other. In some embodiments, an upper portion of the second spacer layer 41B (or the first spacer layer 41A when the second spacer layer 41B is not present) may be removed partially or fully to increase aspect ratio of an opening through which the source/drain region 82N, 82P is formed. FIG. 1A depicts an embodiment in which the upper portion of the second spacer layer 41B is not thinned.

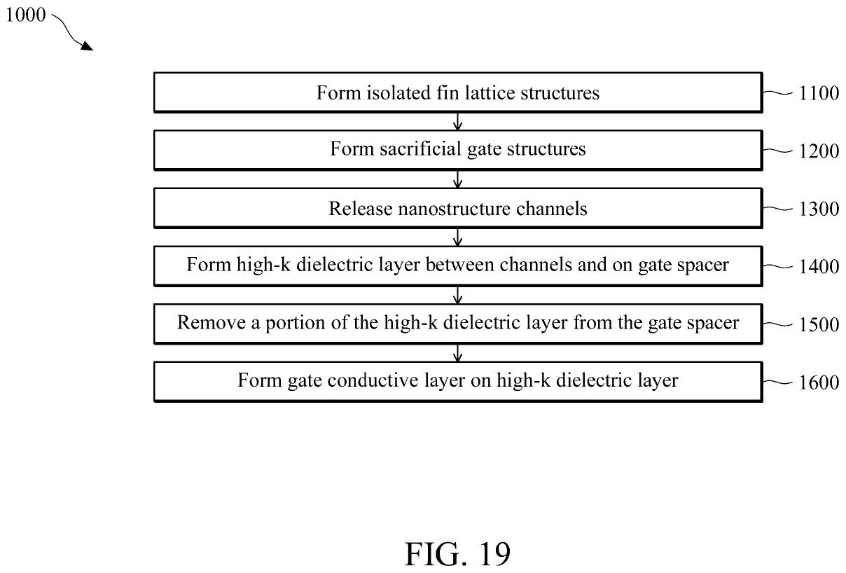

FIG. 19 depicts a flowchart of a method 1000 for forming an IC device or a portion thereof from a workpiece, according to one or more aspects of the present disclosure. Method 1000 is merely an example and not intended to limit the present disclosure to what is explicitly illustrated in method 1000. Additional acts can be provided before, during and after the method 1000 and some acts described can be replaced, eliminated, or moved around for additional embodiments of the method. Not all acts are described herein in detail for reasons of simplicity. Method 1000 is described below in conjunction with fragmentary perspective and/or cross-sectional views of a workpiece, shown in FIGS. 2A-18, at different stages of fabrication according to embodiments of method 1000. For avoidance of doubt, throughout the figures, the X direction is perpendicular to the Y direction and the Z direction is perpendicular to both the X direction and the Y direction. It is noted that, because the workpiece may be fabricated into a semiconductor device, the workpiece may be referred to as the semiconductor device as the context requires.

FIGS. 2A through 18 are views of intermediate stages in the manufacturing of FETs, such as nanostructure FETs, in accordance with some embodiments.

In FIG. 2A and FIG. 2B, a substrate 110 is provided. The substrate 110 may be a semiconductor substrate, such as a bulk semiconductor, or the like, which may be doped (e.g., with a p-type or an n-type dopant) or undoped. The semiconductor material of the substrate 110 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. Other substrates, such as single-layer, multi-layered, or gradient substrates may be used.

Further in FIG. 2A and FIG. 2B, a multi-layer stack 25 or “lattice” is formed over the substrate 110 of alternating layers of first semiconductor layers 21A, 21B, 21C (collectively referred to as first semiconductor layers 21) and second semiconductor layers 23. In some embodiments, the first semiconductor layers 21 may be formed of a first semiconductor material, such as Si, SiGe, Ge, GaAs, InGaAs, MoS, WS2, and the like, and the second semiconductor layers 23 may be formed of a second semiconductor material, such as SiGe, Ge, Si, InGaAs, AlGaAs or the like. Each of the layers 21, 23 of the multi-layer stack 25 may be formed to have thickness in a range of about 1 nm to about 10 nm.

Three layers of the first semiconductor layers 21 and four layers of the second semiconductor layers 23 are illustrated. In some embodiments, the multi-layer stack 25 may include fewer or additional numbers of the first semiconductor layers 21 and the second semiconductor layers 23. Although the multi-layer stack 25 is illustrated as including a second semiconductor layer 23 as the bottommost layer and the topmost layer, in some embodiments, the bottommost layer and/or the topmost layer of the multi-layer stack 25 may be a first semiconductor layer 21.

Due to high etch selectivity between the first semiconductor materials and the second semiconductor materials, the second semiconductor layers 23 of the second semiconductor material may be removed without significantly removing the first semiconductor layers 21 of the first semiconductor material, thereby allowing the first semiconductor layers 21 to be patterned to form channel regions of nano-FETs. In some embodiments, the first semiconductor layers 21 are removed and the second semiconductor layers 23 are patterned to form channel regions. The high etch selectivity allows the first semiconductor layers 21 of the first semiconductor material to be removed without significantly removing the second semiconductor layers 23 of the second semiconductor material, thereby allowing the second semiconductor layers 23 to be patterned to form channel regions of nano-FETs.

In FIGS. 2A and 2B, a sacrificial capping structure 26S is formed on the multi-layer stack 25. The sacrificial capping structure 26S may include third semiconductor layers 29L′, 29U′ having a fourth semiconductor layer 28S′ therebetween. The third semiconductor layers 29L′, 29U′ can include the same semiconductor material (e.g., silicon) as the first semiconductor layers 21. The fourth semiconductor layer 28S′ can include a third semiconductor material, such as a high germanium concentration semiconductor material. The high germanium concentration semiconductor material can be a SiGe material having germanium concentration that exceeds about 50%, such as about 50% to 100% (i.e., pure Ge). In some embodiments, the lower third semiconductor layer 29L′ is formed, then the fourth semiconductor layer 28S′ is formed on the lower third semiconductor layer 29L′, then the upper third semiconductor layer 29U′ is formed on the fourth semiconductor layer 28S′. The lower third semiconductor layer 29L′ and the upper third semiconductor layer 29U′ may still be the same semiconductor material (e.g., silicon) as the first semiconductor layers 21, or may be other semiconductor materials. Formation of the third and fourth semiconductor layers 29L′, 29U′, 28S′ may be similar in most respects to formation of the first and second semiconductor layers 21, 23 described previously.

In FIG. 3A and FIG. 3B, fins 32 are formed in the substrate 110 and nanostructures 22, 24 are formed in the multi-layer stack 25 while third and fourth semiconductor nanostructures 29L, 29U, 28S are also formed, corresponding to act 1100 of FIG. 19. In some embodiments, the nanostructures 22, 24 and the fins 32 may be formed by etching trenches in the multi-layer stack 25, the sacrificial capping structure 26S and the substrate 110. The etching may be any acceptable etch process, such as a reactive ion etch (RIE), neutral beam etch (NBE), the like, or a combination thereof. The etching may be anisotropic. First nanostructures 22A, 22B, 22C (also referred to as “channels 22” below) are formed from the first semiconductor layers 21, and second nanostructures 24 are formed from the second semiconductor layers 23. Third nanostructures 29L, 29U are formed from the third semiconductor layers 29L′, 29U′. Fourth nanostructures 28S are formed from the fourth semiconductor layer 28S′. Distance CD1 between adjacent fins 32 and nanostructures 22, 24 may be from about 18 nm to about 100 nm. A portion of the device 10 is illustrated in FIGS. 3A and 3B including two fins 32 for simplicity of illustration. The process 1000 illustrated in FIG. 19 may be extended to any number of fins and is not limited to the two fins 32 shown in FIGS. 3A-18.

The fins 32 and the nanostructures 22, 24 may be patterned by any suitable method. For example, one or more photolithography processes, including double-patterning or multi-patterning processes, may be used to form the fins 32 and the nanostructures 22, 24. Generally, double-patterning or multi-patterning processes combine photolithography and self-aligned processes, allowing for pitches smaller than what is otherwise obtainable using a single, direct photolithography process. As an example of one multi-patterning process, a sacrificial layer may be formed over a substrate and patterned using a photolithography process. Spacers are formed alongside the patterned sacrificial layer using a self-aligned process. The sacrificial layer is then removed, and the remaining spacers may then be used to pattern the fins 32.

FIGS. 3A and 3B illustrate the fins 32 having tapered sidewalls, such that a width of each of the fins 32 and/or the nanostructures 22, 24 continuously increases in a direction towards the substrate 110. In such embodiments, each of the nanostructures 22, 24 may have a different width and be trapezoidal in shape. In other embodiments, the sidewalls are substantially vertical (non-tapered), such that width of the fins 32 and the nanostructures 22, 24 is substantially similar, and each of the nanostructures 22, 24 is rectangular in shape.

In FIGS. 3A and 3B, isolation regions, features or structures 36, which may be shallow trench isolation (STI) regions, features or structures, are formed adjacent the fins 32. The isolation regions 36 may be formed by depositing an insulation material over the substrate 110, the fins 32, and nanostructures 22, 24, and between adjacent fins 32 and nanostructures 22, 24. The insulation material may be an oxide, such as silicon oxide, a nitride, the like, or a combination thereof, and may be formed by high-density plasma CVD (HDP-CVD), flowable CVD (FCVD), the like, or a combination thereof. In some embodiments, a liner (not separately illustrated) may first be formed along surfaces of the substrate 110, the fins 32, and the nanostructures 22, 24. Thereafter, a core material, such as those discussed above may be formed over the liner.

The insulation material undergoes a removal process, such as a chemical mechanical polish (CMP), an etch-back process, combinations thereof, or the like, to remove excess insulation material over the nanostructures 22, 24. Top surfaces of the nanostructures 22, 24 may be exposed and level with the insulation material after the removal process is complete.

The insulation material is then recessed to form the isolation regions 36. After recessing, the nanostructures 22, 24 and upper portions of the fins 32 may protrude from between neighboring isolation regions 36. The isolation regions 36 may have top surfaces that are flat as illustrated, convex, concave, or a combination thereof. In some embodiments, the isolation regions 36 are recessed by an acceptable etching process, such as an oxide removal using, for example, dilute hydrofluoric acid (dHF), which is selective to the insulation material and leaves the fins 32 and the nanostructures 22, 24 substantially unaltered.

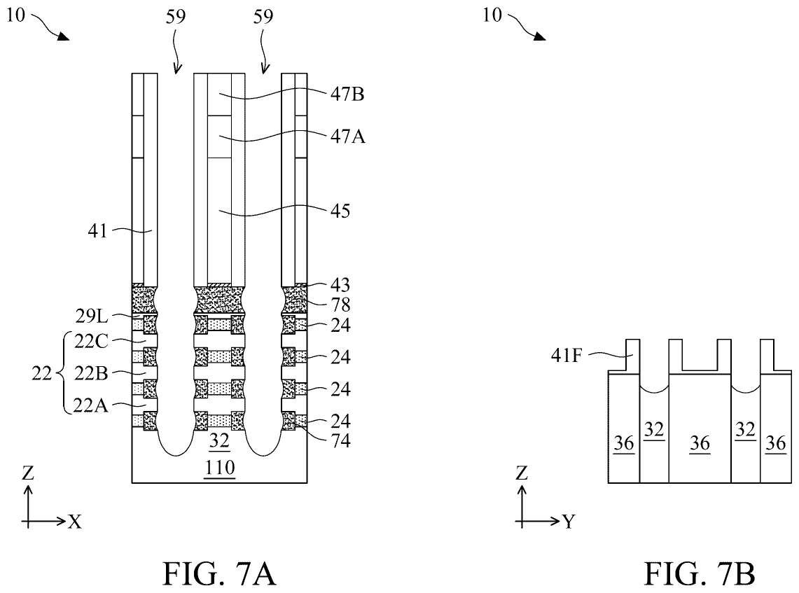

In some embodiments, the fourth semiconductor nanostructure 28S has the same width in the Y-axis direction as the channels 22 due to being formed via an anisotropic etching process that forms the trenches through the stacks 25 and the sacrificial capping structure 26S. As such, in most embodiments, a gate protection top (GPT) hard mask or “dielectric protective layer” 78 (see FIG. 7A) that replaces the fourth semiconductor nanostructure 28S in a later operation has the same width in the Y-axis direction as the channels 22. The GPT hard mask 78 is used to protect the underlying channels 22 during etching of a mask layer 500 used in selective etching of the gate dielectric layer 600. In some embodiments, the GPT hard mask 78 has a width in the Y-axis direction that is slightly greater than a width of the channels 22. In some embodiments, the GPT hard mask 78 has width in the Y-axis direction that exceeds width of the channels 22 in the Y-axis direction. In some embodiments, overhang of the GPT hard mask 78 beyond the channels 22 is in a range of about 0 nm to about 4 nm. Various approaches can be used to effectuate that the GPT hard mask 78 has a width in the Y-axis direction that is slightly greater than a width of the channels 22. For example, a trimming procedure may be performed on the channels 22 using an etchant that is selective to the material of the channels 22 as compared to with respect to the material of the GPT hard mask 78. For example, the etching selectivity of the etchant between the semiconductor material of the channels 22 and the dielectric material of the GPT hard mask 78 may be in a range between about 10× and about 100×, inclusive. In some embodiments, the GPT hard mask 78 has width that is equal to width of the channels 22.

FIGS. 2A through 3B illustrate one embodiment (e.g., etch last) of forming the fins 32 and the nanostructures 22, 24. In some embodiments, the fins 32 and/or the nanostructures 22, 24 are epitaxially grown in trenches in a dielectric layer (e.g., etch first). The epitaxial structures may comprise the alternating semiconductor materials discussed above, such as the first semiconductor materials and the second semiconductor materials.

In FIG. 3A and FIG. 3B, appropriate wells (not separately illustrated) may be formed in the fins 32, the nanostructures 22, 24, and/or the isolation regions 36. Using masks, an n-type impurity implant may be performed in p-type regions of the substrate 110, and a p-type impurity implant may be performed in n-type regions of the substrate 110. Example n-type impurities may include phosphorus, arsenic, antimony, or the like. Example p-type impurities may include boron, boron fluoride, indium, or the like. An anneal may be performed after the implants to repair implant damage and to activate the p-type and/or n-type impurities. In some embodiments, in situ doping during epitaxial growth of the fins 32 and the nanostructures 22, 24 may obviate separate implantations, although in situ and implantation doping may be used together.

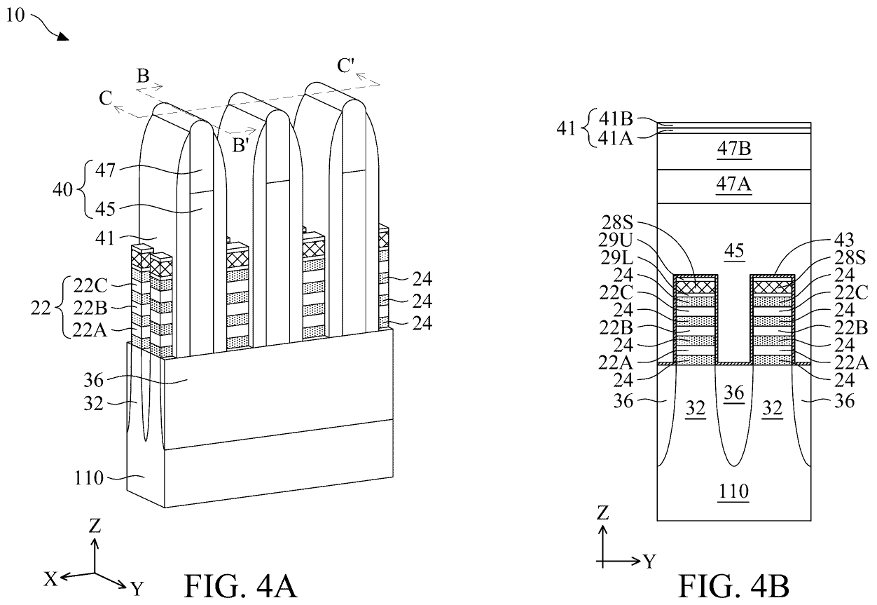

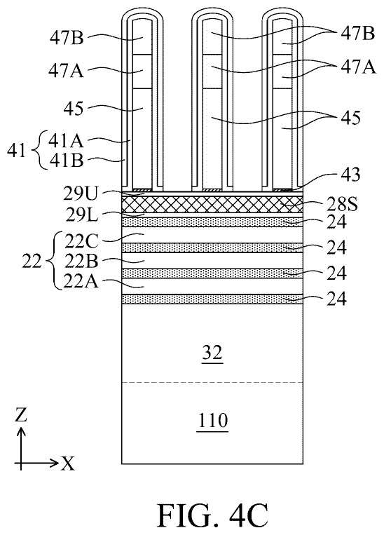

In FIGS. 4A-4C, dummy or sacrificial gate structures 40 are formed over the fins 32, the nanostructures 22, 24 and the third and fourth semiconductor nanostructures 29L, 29U, 28S, corresponding to act 1200 of FIG. 19. A dummy or sacrificial gate layer 45 is formed over the fins 32 and/or the nanostructures 22, 24. The sacrificial gate layer 45 may be or include materials that have a high etching selectivity relative to the isolation regions 36. The sacrificial gate layer 45 may be a conductive, semiconductive or non-conductive material and may be or include amorphous silicon, polycrystalline-silicon (polysilicon), poly-crystalline silicon-germanium (poly-SiGe), metallic nitrides, metallic silicides, metallic oxides, and metals. The sacrificial gate layer 45 may be deposited by physical vapor deposition (PVD), CVD, sputter deposition, or other techniques for depositing the selected material. A mask layer 47 is formed over the sacrificial gate layer 45, and may include, for example, silicon nitride, silicon oxynitride, or the like. In some embodiments, a gate dielectric layer 43 is formed before the sacrificial gate layer 45 between the sacrificial gate layer 45 and the fins 32 and/or the nanostructures 22, 24. In some embodiments, the mask layer 47 includes a first mask layer 47A in contact with the sacrificial gate layer 45, and a second mask layer 47B overlying and in contact with the first mask layer 47A. The first mask layer 47A may be or include the same or different material as that of the second mask layer 47B.

A spacer layer 41 is formed over sidewalls of the mask layer 47 and the sacrificial gate layer 45. The spacer layer 41 is or includes an insulating material, such as SiOCN, SiOC, SiCN or the like (or any of the materials described with reference to FIGS. 1A and 1B) and may have a single-layer structure or a multi-layer structure including a plurality of dielectric layers, in accordance with some embodiments. The spacer layer 41 may be formed by depositing a spacer material layer (not shown) over the mask layer 47 and the sacrificial gate layer 45. Portions of the spacer material layer between sacrificial gate structures 40 are removed using an anisotropic etching process, in accordance with some embodiments. In some embodiments, as shown in detail in FIGS. 4B, 4C, the spacer layer 41 includes a first spacer layer 41A separated from the nanostructure 22C by the sacrificial capping structure 26S, and in contact with the gate dielectric layer 43, the sacrificial gate layer 45 and the first and second mask layers 47A, 47B. A second spacer layer 41B of the spacer layer 41 may be in contact with the first spacer layer 41A. The first spacer layer 41A may be or include the same or different material as that of the second spacer layer 41B.

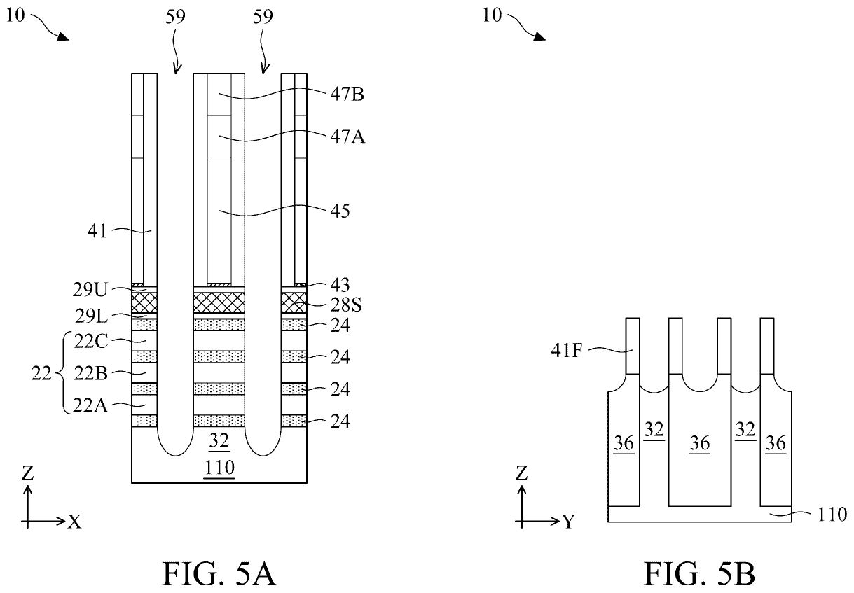

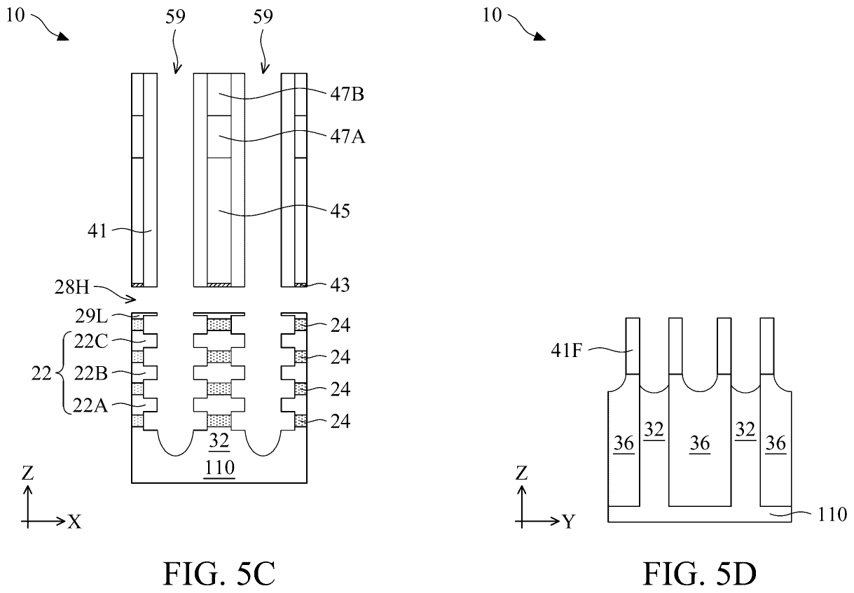

In FIGS. 5A and 5B, source/drain openings 59 are formed by performing an etching process to etch the portions of protruding fins 32, third and fourth semiconductor nanostructures 29L, 29U, 28S and/or nanostructures 22, 24 that are not covered by sacrificial gate structures 40. The recessing may be anisotropic, such that the portions of fins 32 directly underlying sacrificial gate structures 40 and the spacer layer 41 are protected and are not substantially etched. The top surfaces of the recessed fins 32 may be substantially coplanar with the top surfaces of the isolation regions 36, in accordance with some embodiments. The top surfaces of the recessed fins 32 may be lower than the top surfaces of the isolation regions 36, in accordance with some other embodiments, as depicted in FIG. 5B. FIG. 5A depicts three vertical stacks of nanostructures 22, 24 following the etching process for simplicity. In general, the etching process may be used to form fewer or additional vertical stacks of nanostructures 22, 24 over fins 32 than those depicted. In some embodiments, the second mask layer 47B is exposed following the etching process, for example, due to removal of upper portions of the spacer layers 41A, 41B during the etching process. FIG. 5B depicts fin spacers 41F which are portions of the first and/or second spacer layers 41A, 41B that overlie the isolation regions 36 adjacent to respective fins 32.

In FIGS. 5C and 5D, the upper third semiconductor nanostructure 29U and the fourth semiconductor nanostructure 28S are removed and recesses 64 are formed by removing end portions of the nanostructures 24. For example, a selective etching process is performed to recess the end portions of the nanostructures 24 exposed by openings in the spacer layer 41 without substantially attacking the nanostructures 22 or thinning end portions of the nanostructures 22 slightly. In some embodiments, the selective etching process includes a chlorine- or fluorine-based wet etching process. After the selective etching process, recesses 64 are formed in the nanostructures 24 at locations where the removed end portions used to be. Because the fourth semiconductor nanostructure 28S includes the high Ge % semiconductor material and the nanostructures 24 include a lower Ge % semiconductor material, etching of the fourth semiconductor nanostructure 28S can proceed faster than that of the nanostructures 24, such that the entire fourth semiconductor nanostructure 28S can be removed while only end portions of the nanostructures 24 are removed. The upper third semiconductor nanostructure 29U may have thickness in the Z-axis direction that is thinner than that of the lower third semiconductor nanostructure 29L, which can result in the upper third semiconductor nanostructure 29U being removed entirely while the lower third semiconductor nanostructure 29L is only partially removed. Removal of the fourth semiconductor nanostructures 28S results in formation of openings 28H where the fourth semiconductor nanostructures 28S were positioned.

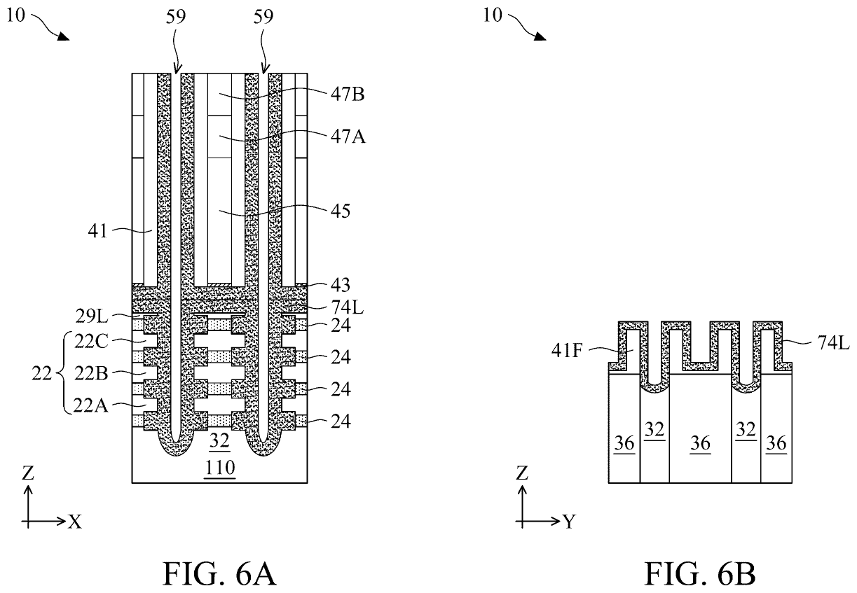

Then, in FIGS. 6A and 6B, following formation of the recesses 64 and the openings 28H, an inner spacer layer 74L is formed to fill (partially or entirely) the recesses 64 in the nanostructures 24 and the openings 28H formed by the previous selective etching process. The inner spacer layer 74L can entirely fill the openings 28H that remain after removing the upper third semiconductor nanostructure 29U and the fourth semiconductor nanostructure 28S. In some embodiments, a seam or air gap may be present in the material of the inner spacer layer 74L in the openings 28H. The inner spacer layer 74L may be a suitable dielectric material, such as silicon carbon nitride (SiCN), silicon oxycarbonitride (SiOCN), or the like, formed by a suitable deposition method such as PVD, CVD, ALD, or the like.

In FIGS. 7A and 7B, following formation of the inner spacer layer 74L, an etching process, such as an anisotropic etching process, is performed to remove portions of the inner spacer layer 74L disposed outside the recesses 64 and the openings 28H, for example, on sidewalls of the nanostructures 22, the gate spacers 41 and the fins 32. The remaining portions of the inner spacer layer 74L (e.g., portions disposed inside the recesses in the nanostructures 24) form the inner spacers 74 and a gate protection top (GPT) hard mask 78. Because the inner spacers 74 and the GPT hard mask 78 are formed in the same deposition and etching operations, the materials of the inner spacers 74 and the GPT hard mask 78 are the same material. The GPT hard mask 78 and the channels 22 may have the same width in the Y-axis direction due to being formed via the same process that forms the source/drain openings 59. In some embodiments, thickness of the GPT hard mask 78 in the Z-axis direction is in a range of about 1 nm to about 10 nm.

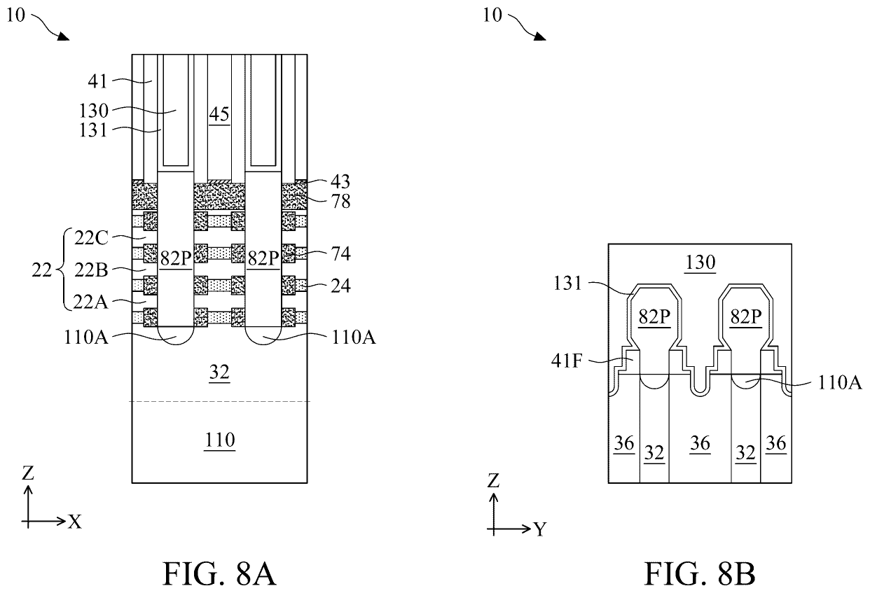

In FIG. 8A, a first semiconductor layer 110A is formed in the source/drain openings 59. The first semiconductor layer 110A is an undoped silicon layer in some embodiments that may be deposited or epitaxially grown on exposed surfaces of the fin 32. The deposition may include one or more operations, such as a CVD, which may be an ultra-high vacuum chemical vapor deposition (UHV-CVD), which allows for improved control of deposition rate and purity of the first semiconductor layer 110A. In some embodiments, precursor gases containing silicon may be introduced into a processing chamber, and a reaction therebetween forms the silicon material, which deposits into the source/drain openings 59. In some embodiments, the first semiconductor layer 110A has an upper surface that is at a level substantially coplanar with an upper surface of the fin 32.

FIG. 8A also depicts formation of source/drain regions 82P or “source/drains 82P” in accordance with various embodiments. In the illustrated embodiment, the source/drain regions 82P are epitaxially grown from epitaxial material(s). In some embodiments, the source/drain regions 82P exert stress in the respective channels 22A, 22B, 22C, thereby improving performance. The source/drain regions 82P are formed such that each sacrificial gate structure 40 is disposed between respective neighboring pairs of the source/drain regions 82P. In some embodiments, the spacer layer 41 separates the source/drain regions 82P from the sacrificial gate layer 45 by an appropriate lateral distance to prevent electrical bridging to subsequently formed gates of the resulting device. The source/drain regions 82P may be or include Si:B, Si:Ga, SiGe:B, SiGe:B:Ga, SiGe:Sn, SiGe:B:Sn or the like. The source/drain regions 82P may exert a compressive strain in the channel regions. The source/drain regions 82P may have surfaces raised from respective surfaces of the first semiconductor layer 110A and may have facets. Neighboring source/drain regions 82P may merge in some embodiments to form a singular source/drain region 82P adjacent two neighboring fins 32. Although omitted from view in FIGS. 8A and 8B, the device 10 may include N-type source/drains 82N (see FIG. 1A) that are formed prior to or following the formation of the P-type source/drains 82P. The N-type source/drains 82N may be or include any of the semiconductor materials described with reference to FIGS. 1A and 1B. The source/drains 82N may be formed by an epitaxial growth process that is similar in most respects to that used to form the source/drains 82P, differing in precursor gas and/or dopant gas ratios, for example.

In FIG. 8B, following formation of the source/drain regions 82N, 82P, the ILD 130 may be formed covering the source/drain regions 82N, 82P and abutting the spacer layer 41. In some embodiments, the ESL 131 is formed prior to forming the ILD 130. The ESL 131 may be formed by depositing a conformal thin layer of a dielectric material different from that of the ILD 130, such as one or more of SiN, SiCN, SiC, SiOC, SiOCN, HfO₂, ZrO₂, ZrAlOx, HfAlOx, HfSiOx, Al₂O₃, or other suitable material. Following deposition of the ESL 131, the ILD 130 may be deposited by a suitable process, such as a blanket deposition process, including PVD, CVD, ALD, or the like. The material of the ILD 130 may include silicon dioxide or a low-k dielectric material (e.g., a material having a dielectric constant (k-value) lower than the k-value (about 3.9) of silicon dioxide). The low-k dielectric material may include silicon oxynitride, phosphosilicate glass (PSG), borosilicate glass (BSG), borophosphosilicate glass (BPSG), undoped silicate glass (USG), fluorinated silicate glass (FSG), silicon oxycarbide (SiOxCy), Spin-On-Glass (SOG) or a combination thereof. The ILD 130 may be deposited by spin-on coating, CVD, flowable CVD (FCVD), PECVD, PVD, or another deposition process.

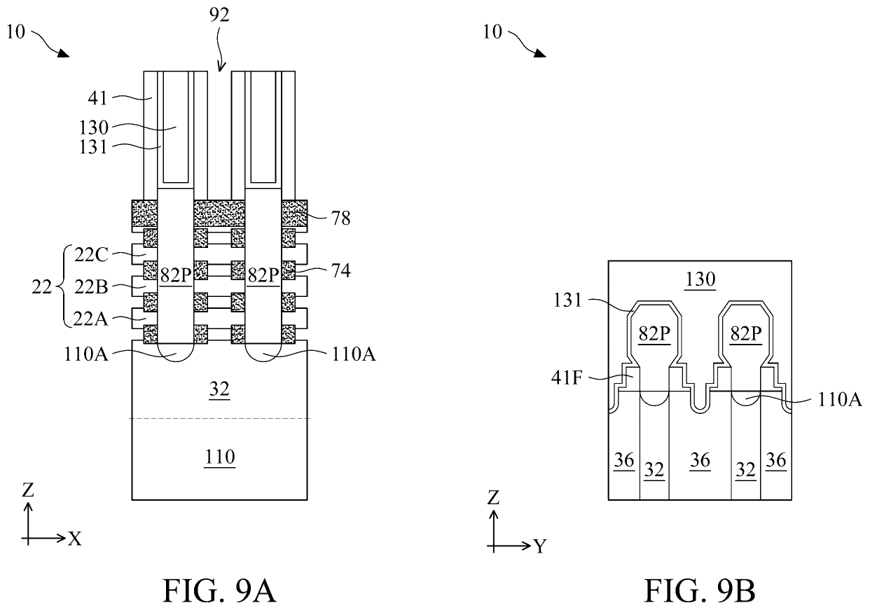

In FIGS. 9A-16B, following formation of the source/drains 82N, 82P, the ESL 131 and the ILD 130, active gate structures 200 may be formed. A planarization process, such as a chemical mechanical polishing (CMP) process, is performed on the ILD 130 and the ESL 131. The hard masks 47A, 47B and portions of the gate spacers 41 are also removed in the planarization process. After the planarization process, the sacrificial gate layers 45 are exposed. The top surfaces of the ILD 130 and the ESL 131 may be coplanar with the top surfaces of the sacrificial gate layers 45 and the gate spacers 41.

Next, as depicted in FIGS. 9A and 9B, the sacrificial gate layer 45 is removed in an etching process, so that openings or “gate trenches” 92 are formed. In some embodiments, the sacrificial gate layer 45 is removed by an anisotropic dry etch process. For example, the etching process may include a dry etch process using reaction gas(es) that selectively etch the sacrificial gate layer 45 without etching the spacer layer 41. The sacrificial gate dielectric 43, when present, may be used as an etch stop layer when the sacrificial gate layer 45 is etched. The sacrificial gate dielectric 43 may then be removed after the removal of the sacrificial gate layer 45.

The nanostructures 24 are removed to release the nanostructures 22, corresponding to act 1300 of FIG. 19. After the nanostructures 24 are removed, the nanostructures 22 form a plurality of nanosheets that extend horizontally (e.g., parallel to a major upper surface of the substrate 110). In some embodiments, the nanostructures 24 are removed by a selective etching process using an etchant that is selective to the material of the nanostructures 24, such that the nanostructures 24 are removed without substantially attacking the nanostructures 22. In some embodiments, the etching process is an isotropic etching process using an etching gas, and optionally, a carrier gas, where the etching gas comprises F2 and HF, and the carrier gas may be an inert gas such as Ar, He, N2, combinations thereof, or the like.

In some embodiments, the nanostructures 24 are removed and the nanostructures 22 are patterned to form channel regions of both PFETs and NFETs. However, in some embodiments the nanostructures 24 may be removed and the nanostructures 22 may be patterned to form channel regions of NFETs, and nanostructures 22 may be removed and the nanostructures 24 may be patterned to form channel regions of PFETs. In some embodiments, the nanostructures 22 may be removed and the nanostructures 24 may be patterned to form channel regions of NFETs, and the nanostructures 24 may be removed and the nanostructures 22 may be patterned to form channel regions of PFETs. In some embodiments, the nanostructures 22 may be removed and the nanostructures 24 may be patterned to form channel regions of both PFETs and NFETs.

In some embodiments, the nanosheets 22 are reshaped (e.g., thinned) by a further etching process to improve gate fill window. The reshaping may be performed by an isotropic etching process selective to the nanosheets 22. After reshaping, the nanosheets 22 may exhibit the dog bone shape in which middle portions of the nanosheets 22 are thinner than peripheral portions of the nanosheets 22 along the X direction. In the embodiments depicted in FIG. 9A, the middle portions are thicker than the peripheral portions.

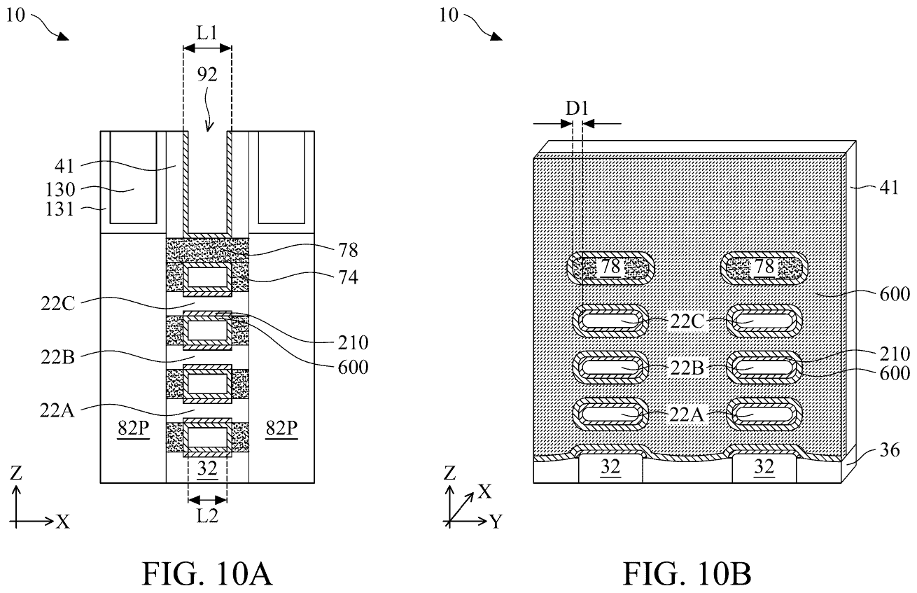

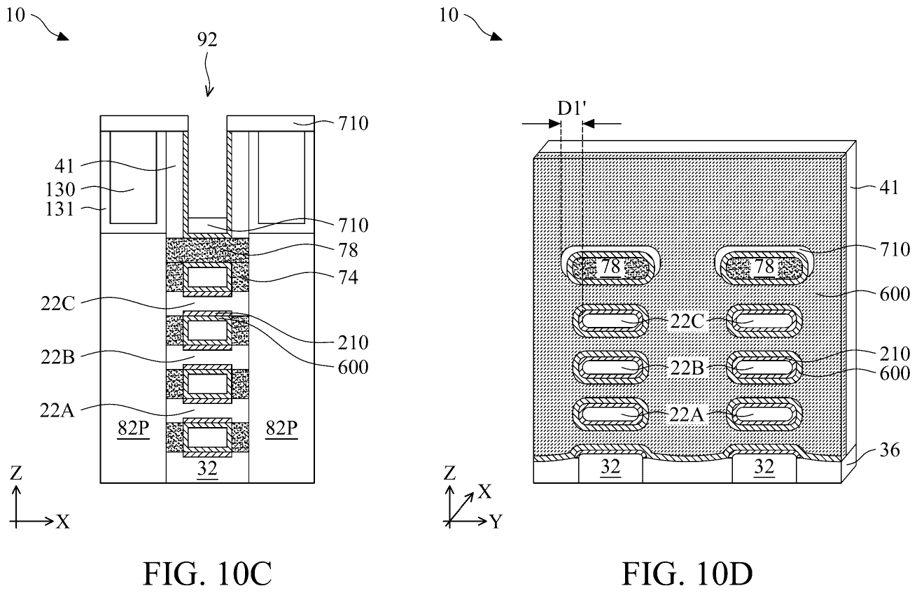

Then, replacement gates 200 are formed. The replacement gates 200 may be referred to as active gates 200 or gate structures 200. The gate structures 200 may be formed by a series of deposition operations, such as ALD cycles, that deposit the various layers of the gate structure 200 in the openings, described below with reference to FIG. 17. Formation of the gate structure 200 is described in detail with reference to FIG. 17 to provide context for understanding the embodiments described with reference to FIGS. 10A-16B.

FIG. 17 is a detailed view of a portion of the gate structure 200. The gate structure 200 generally includes the interfacial layer (IL, or “first IL” below) 210, at least one gate dielectric layer 600, the work function metal layer 900, and the gate fill layer 290. In some embodiments, each replacement gate 200 further includes at least one of a second interfacial layer 240 or a second work function layer 700.

With reference to FIG. 17, in some embodiments, the first IL 210 includes an oxide of the semiconductor material of the substrate 110, e.g., silicon oxide. In other embodiments, the first IL 210 may include another suitable type of dielectric material. The first IL 210 has a thickness in a range between about 5 angstroms and about 50 angstroms. The first IL 210 may be formed by thermal oxidation or another suitable process that oxidizes the semiconductor material of the channels 22 and the fin 32.

Still referring to FIG. 17, the gate dielectric layer 600 is formed over the first IL 210. In some embodiments, an atomic layer deposition (ALD) process is used to form the gate dielectric layer 600 to control thickness of the deposited gate dielectric layer 600 with precision. In some embodiments, the ALD process is performed using between about 40 and 80 deposition cycles, at a temperature range between about 200 degrees Celsius and about 300 degrees Celsius. In some embodiments, the ALD process uses HfCl₄ and/or H₂O as precursors. Such an ALD process may form the dielectric layer 600 to have a thickness in a range between about 10 angstroms and about 100 angstroms.

In some embodiments, the gate dielectric layer 600 includes a high-k dielectric material, which may refer to dielectric materials having a high dielectric constant that is greater than a dielectric constant of silicon oxide (k≈3.9). Exemplary high-k dielectric materials include HfO₂, HfSiO, HfSiON, HfTaO, HfTiO, HfZrO, ZrO₂, Ta₂O₅, or combinations thereof. In other embodiments, the gate dielectric layer 600 may include a non-high-k dielectric material such as silicon oxide. In some embodiments, the gate dielectric layer 600 includes more than one high-k dielectric layer, of which at least one includes dopants, such as lanthanum, magnesium, yttrium, or the like, which may be driven in by an annealing process to modify threshold voltage of the nanostructure devices 20A, 20B.

In embodiments of the disclosure, the gate dielectric layer 600 is reshaped via a selective etching process that removes material of the gate dielectric layer 600 from side surfaces of the gate spacers 41, which can improve device performance, such as by reducing capacitance between the gate structure 200 and the source/drains 82P. The gate dielectric layer 600 being present on the surfaces of the channels 22 is beneficial to improve isolation between the gate structure 200 and the channels 22. The gate dielectric layer 600 being present on the surfaces of the inner spacers 74 is beneficial to increase on current “ION” of nanostructure FETs, such as the nanostructure devices 20A, 20B. As such, in embodiments of the disclosure, the gate dielectric layer 600 remains on the channels 22 and the inner spacers 74 and is removed from the gate spacer 41. Processes for selectively removing the gate dielectric layer 600 are described with reference to FIGS. 10A-16B.

With further reference to FIG. 17, following formation of the gate dielectric layer 600, a metal layer 290 is formed on the gate dielectric layer 600. Additional layers, such as a second IL 240, a second work function layer 700 and a work function metal layer 900 may be formed prior to formation of the metal layer 290. For example, an optional second IL 240 is formed on the gate dielectric layer 600, and the second work function layer 700 is formed on the second IL 240. The second IL 240 promotes better metal gate adhesion on the gate dielectric layer 600. In many embodiments, the second IL 240 further provides improved thermal stability for the gate structure 200 and serves to limit diffusion of metallic impurities from the work function metal layer 900 and/or the work function barrier layer 700 into the gate dielectric layer 600. In some embodiments, formation of the second IL 240 is accomplished by first depositing a high-k capping layer (not illustrated for simplicity) on the gate dielectric layer 600. The high-k capping layer comprises one or more of the following: HfSiON, HfTaO, HfTiO, HfTaO, HfAlON, HfZrO, or other suitable materials, in various embodiments. In one embodiment, the high-k capping layer comprises titanium silicon nitride (TiSiN). In some embodiments, the high-k capping layer is deposited by an ALD using about 40 to about 100 cycles at a temperature of about 400 degrees C. to about 450 degrees C. A thermal anneal is then performed to form the second IL 240, which may be or comprise TiSiNO, in some embodiments. Following formation of the second IL 240 by thermal anneal, an atomic layer etch (ALE) with artificial intelligence (AI) control may be performed in cycles to remove the high-k capping layer while substantially not removing the second IL 240. Each cycle may include a first pulse of WCl₅, followed by an Ar purge, followed by a second pulse of O₂, followed by another Ar purge. The high-k capping layer is removed to increase gate fill window for further multiple threshold voltage tuning by metal gate patterning.

Further in FIG. 17, after forming the second IL 240 and removing the high-k capping layer, the work function barrier layer 700 is optionally formed on the gate structure 200, in accordance with some embodiments. The work function barrier layer 700 is or comprises a metal nitride, such as TiN, WN, MON, TaN, or the like. In a specific embodiment, the work function barrier layer 700 is TiN. The work function barrier layer 700 may have thickness ranging from about 5 A to about 20 A. Inclusion of the work function barrier layer 700 provides additional threshold voltage tuning flexibility. In general, the work function barrier layer 700 increases the threshold voltage for NFET transistor devices and decreases the threshold voltage (magnitude) for PFET transistor devices.

The work function metal layer 900, which may include at least one of an N-type work function metal layer, an in-situ capping layer, or an oxygen blocking layer, is formed on the work function barrier layer 700, in some embodiments. The N-type work function metal layer is or comprises an N-type metal material, such as TiAlC, TiAl, TaAlC, TaAl, or the like. The N-type work function metal layer may be formed by one or more deposition methods, such as CVD, PVD, ALD, plating, and/or other suitable methods, and has a thickness between about 10 A and 20 A. The in-situ capping layer is formed on the N-type work function metal layer. In some embodiments, the in-situ capping layer is or comprises TIN, TiSiN, TaN, or another suitable material, and has a thickness between about 10 A and 20 A. The oxygen blocking layer is formed on the in-situ capping layer to prevent oxygen diffusion into the N-type work function metal layer, which would cause an undesirable shift in the threshold voltage. The oxygen blocking layer is formed of a dielectric material that can stop oxygen from penetrating to the N-type work function metal layer, and may protect the N-type work function metal layer from further oxidation. The oxygen blocking layer may include an oxide of silicon, germanium, SiGe, or another suitable material. In some embodiments, the oxygen blocking layer is formed using ALD and has a thickness between about 10 A and about 20 A.

FIG. 17 further illustrates the metal core layer 290. In some embodiments, a glue layer (not separately illustrated) is formed between the oxygen blocking layer of the work function metal layer and the metal core layer 290. The glue layer may promote and/or enhance the adhesion between the metal core layer 290 and the work function metal layer 900. In some embodiments, the glue layer may be formed of a metal nitride, such as TiN, TaN, MON, WN, or another suitable material, using ALD. In some embodiments, thickness of the glue layer is between about 10 A and about 25 A. The metal core layer 290 may be formed on the glue layer, and may include a conductive material such as tungsten, cobalt, ruthenium, iridium, molybdenum, copper, aluminum, or combinations thereof. In some embodiments, the metal core layer 290 may be deposited using methods such as CVD, PVD, plating, and/or other suitable processes. In some embodiments, a seam 510, which may be an air gap, is formed in the metal core layer 290 vertically between the channels 22A, 22B, 22C. In some embodiments, the metal core layer 290 is conformally deposited on the work function metal layer 900. The seam 510 may form due to sidewall deposited film merging during the conformal deposition. In some embodiments, the seam 510 is not present between the neighboring channels 22A, 22B, 22C.

In some embodiments, one or more of metal layers including the core layer 290 and the work function layers 700, 900 in PFET devices can include Ti, Al, Zn, W, Nb, Co and the like and total thickness of the combination of metal layers on the gate dielectric layer 600 may be in a range of about 0.5 nm to about 20 nm. In some embodiments, one or more of metal layers including the core layer 290 and the work function layers 700, 900 in NFET devices can include Ti and/or Al and the like and total thickness of the combination of metal layers on the gate dielectric layer 600 may be in a range of about 0.5 nm to about 20 nm.

In FIGS. 10A-10D, the high-k dielectric layer 600 is formed as described with reference to FIG. 17 above, corresponding to act 1400 of FIG. 19. The high-k dielectric layer 600 may be present on the channels 22, the fin 32, the GPT hard mask 78, the inner spacers 74 and the gate spacer 41. The high-k dielectric layer 600 may be in direct contact with the inner spacers, the GPT hard mask 78 and the gate spacer 41 and may be separated from the channels 22 by the first IL 210.

FIG. 10A depicts spacing L1 or gap length L1 between the gate spacers 41 on either side of the gate opening 92. The spacing L1 may also be referred to as “poly gate length.” In some embodiments, the spacing L1 is in a range of about 8 nm to about 15 nm. FIG. 10A also depicts spacing L2 between inner spacers 74 including width of the high-k dielectric layer 600 on side surfaces thereof. The spacing L2 can also be referred to as “inner gate length.” In some embodiments, the spacing L2 is in a range of about 8 nm to about 15 nm. In some embodiments, the spacings L1 and L2 are equal to each other or not equal to each other.

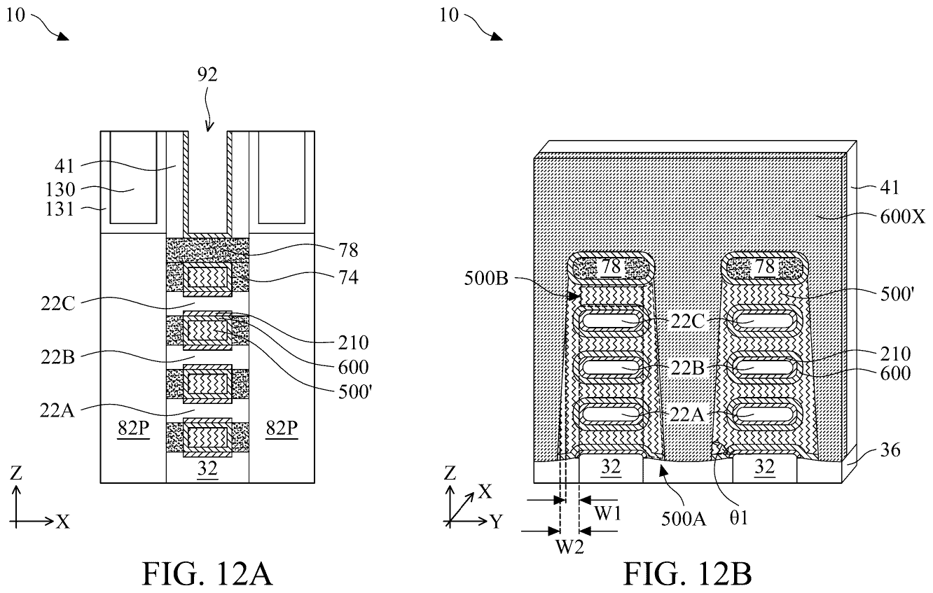

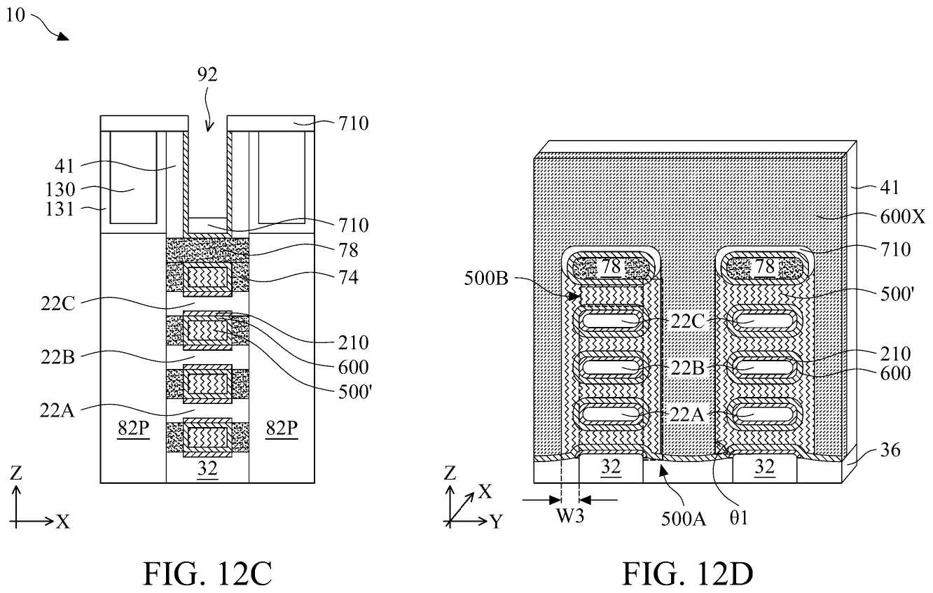

As depicted in FIG. 10B, the GPT hard mask 78 may overhang the channels 22 by a distance D1. In some embodiments, the distance D1 is in a range of 0 nm (i.e., no overhang) to about 4 nm. In a later process described with reference to FIGS. 12A-12D, the overhang of the GPT hard mask 78 is beneficial to protect the channels 22 during etching of a mask layer 500 and increased overhang can improve process window of the etching process that etches the mask layer 500. However, the overhang also results in additional material of the high-k dielectric layer 600 remaining on the gate spacer 41 after selective etching.

In FIGS. 10C and 10D, an additional transition metal capping layer 710 (or simply, “capping layer 710”) is formed on the GPT hard mask 78 that increases the overhang, which can be beneficial to allow a higher etching rate that can result in an non-tapered or vertical profile of the high-k dielectric layer 600 after selective etching. In some embodiments, the transition metal capping layer 710 is or includes TiN that can be formed via a suitable deposition process, such as a PVD. Due to depth of the surfaces of the isolation regions 36, the PVD TiN may not deposit on the isolation regions 36. The PVD TiN generally does not deposit on the underlying nanostructures 22 due to protection by the GPT hard mask 78. In some embodiments, inclusion of the PVD TiN capping layer 710 can result in an extension of the overhang to an extended distance D1′ depicted in FIG. 10D. Difference between the extended distance D1′ and the distance D1 (e.g., extra overhang obtained due to the capping layer 710) can be in a range of about 0.5 nm to about 4 nm, inclusive. The capping layer 710 may additionally be formed on upper surfaces of the gate spacers 41, the ILD 130 and the ESL 131, which may also result in overhang at the upper end of the gate trench 92, as depicted in FIG. 10C.

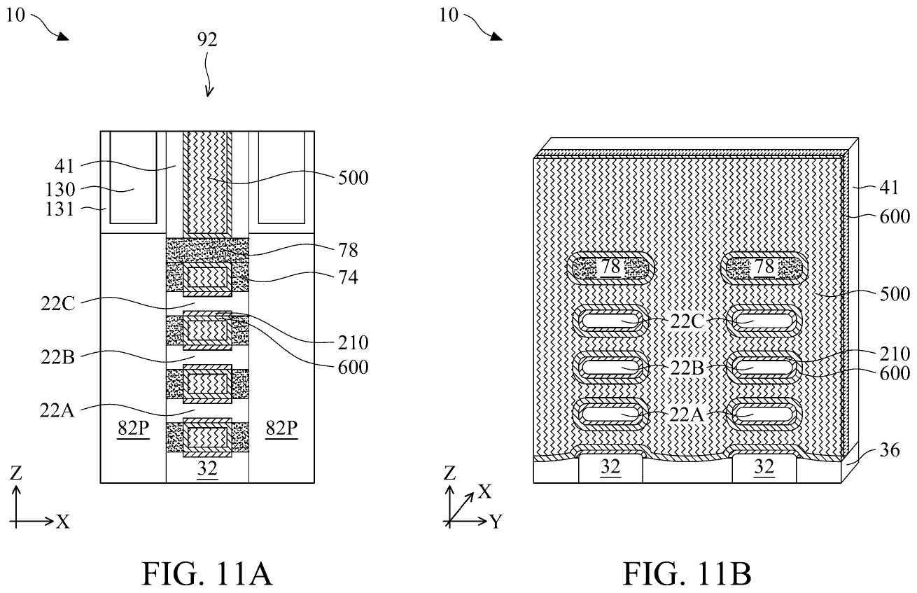

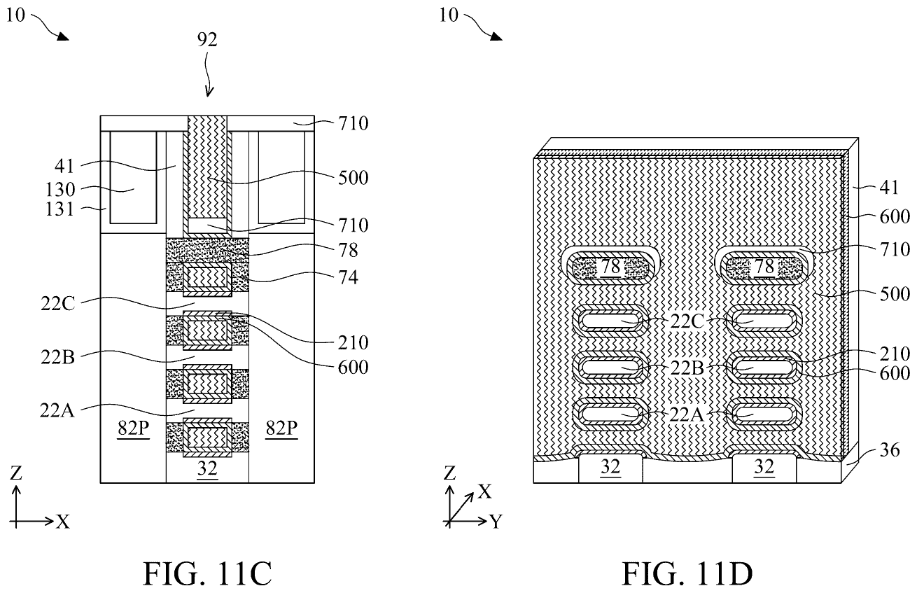

In FIGS. 11A-11D, a mask layer 500 is formed in the gate trench 92 that covers the channels 22, the GPT hard mask 78 and the optional capping layer 710. In some embodiments, the mask layer 500 is a bottom antireflective coating (BARC) layer and is referred to as the BARC layer 500. The process of forming the BARC layer 500 in the gate trench 92 can begin with one or more cleaning processes, such as RCA cleaning (a clean involving a mixture of hydrogen peroxide, ammonia, and water), to prepare exposed surfaces for BARC adhesion. The BARC material is then applied to the device 10. This can be done using spin-coating for liquid BARCs or chemical vapor deposition (CVD) for inorganic BARCs. During spin-coating, the device 10 may be spun at high speeds to spread the BARC material evenly across the surface, including the walls and bottom of the gate trenches 92. After application, the BARC layer 500 can undergo a baking process to remove solvent (in the case of liquid BARCs) and to improve material properties, such as adhesion to the device 10 and optical characteristics thereof.

In FIGS. 12A-12D, following formation of the BARC layer 500, one or more removal processes can be performed to remove portions of the BARC layer 500 that are outside the channels 22 and the inner spacers 74. The removal process(es) can include one or more etching processes. In some embodiments, the etching process can involve wet chemical etching, dry plasma etching, or reactive ion etching (RIE), among other techniques. In some embodiments, the etching process involves material removal through chemical reactions or physical sputtering. For example, plasma etching can use a reactive plasma to remove the material of the BARC layer 500. Selection of etching chemistry and process parameters can be beneficial for effectively removing the BARC layer 500 without damaging underlying layers or structures, such as the channels 22 and the isolation structures 36. Etching chemistries can include oxygen (O₂) plasma, which can generate reactive oxygen species (ROS) such as atomic oxygen, which react with carbon in the organic BARC layer 500, converting it into volatile compounds like carbon dioxide (CO₂) and water (H₂O). In some embodiments, argon is added to the oxygen plasma to enhance the physical sputtering effect, helping to remove the organic material more efficiently. Argon atoms, being inert, may not react chemically but contribute to the physical removal of material through ion bombardment. In some embodiments, hydrogen is added to the plasma to facilitate the removal of oxygen-containing groups within the BARC material, further promoting its conversion to volatile products. Process parameters can include RF power, which is power applied to generate the plasma. The RF power can significantly affect etching rate and selectivity. Higher power levels increase the density of reactive species, leading to faster etching rates. Too high power can also increase damage to underlying structures. Other process parameters can include chamber pressure, gas flow rates, temperature and etching time. Chamber pressure during etching can affect mean free path of reactive species and ions, influencing the etching uniformity and rate. Lower pressures can be used for anisotropic etching, while higher pressures promote chemical reactions by increasing the density of reactive species. The rates at which the etching gases are introduced into the chamber can be selected to provide sufficient supply of reactive species for the etching reaction while avoiding excess which can lead to non-uniform etching or damage. Substrate and chamber temperatures can affect the reaction rates and byproduct volatility. In some embodiments, the temperature is kept moderate to provide efficient etching without compromising integrity of the substrate or nearby structures. After plasma etching of the BARC layer 500, a post-etch cleaning step may be necessary to remove any residues or byproducts left on the substrate. This step can often involve wet chemical cleans or additional plasma treatments selected to improve cleaning of the substrate.

For example, the GPT hard mask 78 may function as a mask to prevent portions of the BARC layer 500 under the GPT hard mask 78 from being removed. For example, a reactive ion etching (RIE) dry etching process may be used to pattern the BARC layer 500 to achieve the BARC layer 500′ that remains on the channel layers 22 and the high-k dielectric layer 600. In some embodiments, because the GPT hard mask 78 has a width that extends beyond the width of the channel layers 22, the BARC layer 500′ post etching remains on sidewalls of the channel layers 22. In some embodiments, the BARC layer 500′ post etching wraps around the channel layers 22 and the high-k dielectric layer 600.

As depicted in FIG. 12B, the BARC layer 500′ post etching can have tapered sidewalls in the Y-Z plane. Namely, distance W1 between the top nanostructure 22C and the outer sidewall of the BARC layer 500′ and distance W2 between the bottom nanostructure 22A and the outer sidewall of the BARC layer 500′ can be different. For example, the distance W2 can exceed the distance W1, meaning that the width of the BARC layer 500′ in the Y-axis direction increases with proximity to the fin 32 and decreases with proximity to the GPT hard mask 78. In some embodiments, the distance W1 can be in a range of about 1.5 nm to about 20 nm. The BARC layer 500′ can extend from a side surface or corner of the high-k dielectric layer 600 on the GPT hard mask 78 to a position on the isolation region 36. A taper angle θ1 between the plane of the upper surface of the isolation region 36 and the outer sidewall of the BARC layer 500′ can be in a range of about 60 degrees to about 85 degrees.

In FIG. 12D, due to additional overhang provided by the PVD TiN capping layer 710, a higher etching rate may be used, which can result in less tapering of the outer sidewalls of the BARC layer 500′. The higher etching rate may be achieved by one or a combination of the parameters described above. As a result of the higher etching rate, taper angle θ1 between the plane of the upper surface of the isolation region 36 and the outer sidewall of the BARC layer 500′ can be in a range of about 85 degrees to 90 degrees. FIG. 12D depicts a distance W3 between the nanostructures 22 and the outer sidewall of the BARC layer 500′. Due to the increased etching rate, the distance W3 can be substantially uniform with increased proximity to the fin 32 and/or the GPT hard mask 78 and can be in a range of about 1.5 nm to about 20 nm.

FIGS. 12B and 12D also depict that the BARC layer 500′ can include inner spacer regions 500B that overlap inner spacers 74 between the channels 22 and between the channel 22A and the fin 32. The BARC layer 500′ can also include extension regions 500A laterally outside or adjacent the channels 22. The extension regions 500A can have non-uniform width in the Y-axis direction due to tapering or can have substantially uniform or uniform width in the Y-axis direction due to the higher etching rate when the capping layer 710 is in place.

Following the etching operation that shapes the BARC layer 500 to form the BARC layer 500′, the BARC layer 500′ covers the high-k dielectric layer 600 on the channels 22, the inner spacers 74 and a small portion of the gate spacer 41 associated with the extension regions 500A. The BARC layer 500′ exposes excess material 600X of the high-k dielectric layer 600 that is on the gate spacer 41. Generally, the excess material 600X extends above the GPT hard mask 78 and also includes portions that are laterally between the stacks of channels 22.

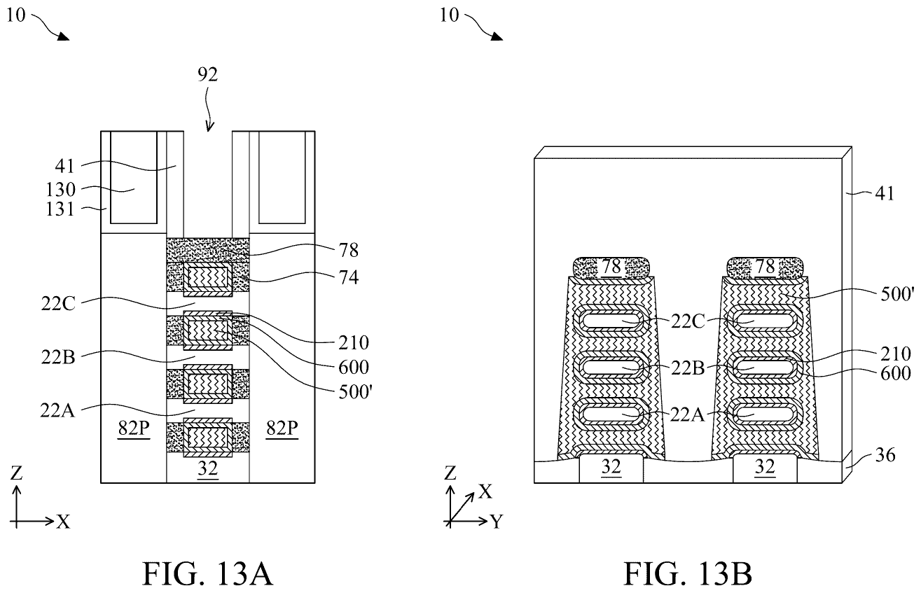

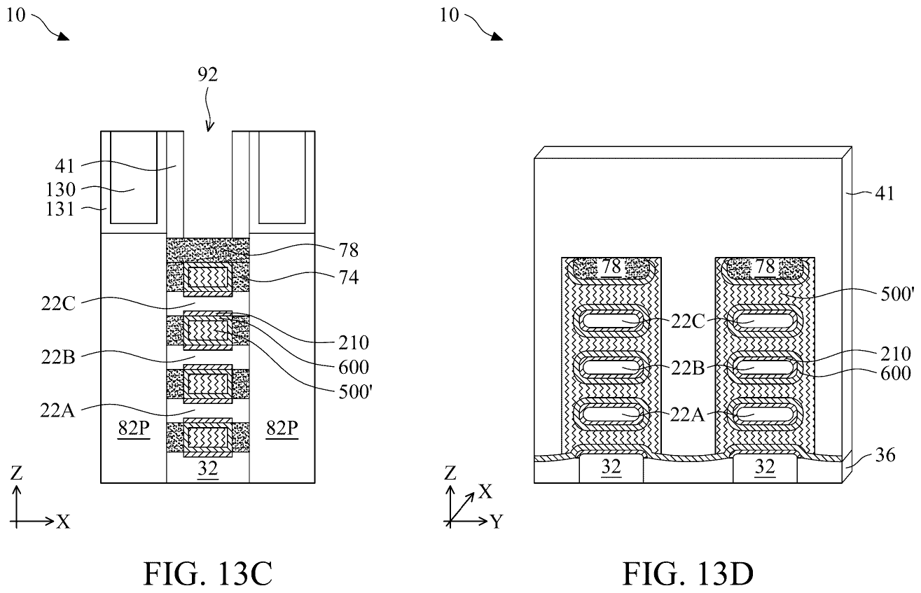

In FIGS. 13A-13D, the excess material 600X of the high-k dielectric layer 600 is removed, corresponding to act 1500 of FIG. 19. The excess material 600X of the high-k dielectric layer 600 may be removed by one or more etching operations that remove material of the high-k dielectric layer 600 without substantially attacking the BARC layer 500′, the gate spacers 41 and the isolation regions 36. The excess material 600X may be removed by a suitable etch operation, such as a wet chemical etch that uses a dilute hydrofluoric acid or a buffered oxide etch or a dry etch, such as a chlorine-based plasma etch. In addition to the excess material 600X, the etching operation(s) may remove or thin the high-k dielectric layer 600 on the top surface of the GPT hard mask 78 and may remove the high-k dielectric layer 600 on the upper surface of the isolation regions 36. In FIG. 13B, without the capping layer 710 in place, the etch operation(s) may remove the high-k dielectric layer 600 on the upper and side surfaces of the GPT hard mask 78, and may leave portions of the high-k dielectric layer 600 on bottom corner regions of the GPT hard mask 78, as shown. In FIG. 13D, the capping layer 710 extends past the side surfaces of the high-k dielectric layer 600 on the GPT hard mask 78, resulting in the high-k dielectric layer 600 being in place on the side surfaces of the GPT hard mask 78 following the etching operation(s). In some embodiments, the portion of BARC layer 500′ laterally adjacent to the GPT hard mask 78 is separated from the GPT hard mask 78 by the high-k dielectric layer 600.

In FIGS. 13C and 13D, the capping layer 710 is removed following or simultaneously with the etching of the high-k dielectric layer 600. The capping layer 710 may be removed by a suitable etching operation, such as a wet etch or a dry etch including chlorine- or fluorine-based plasmas.

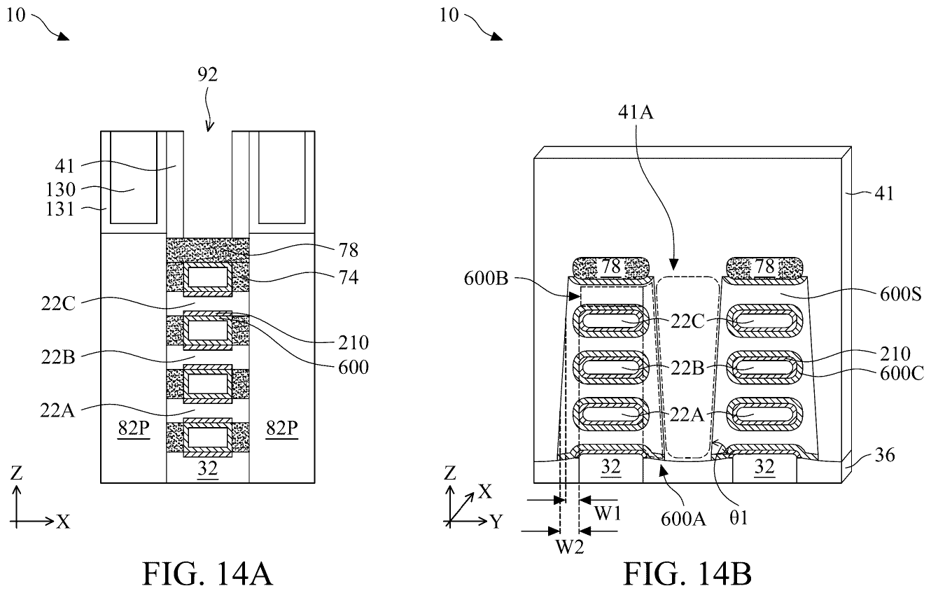

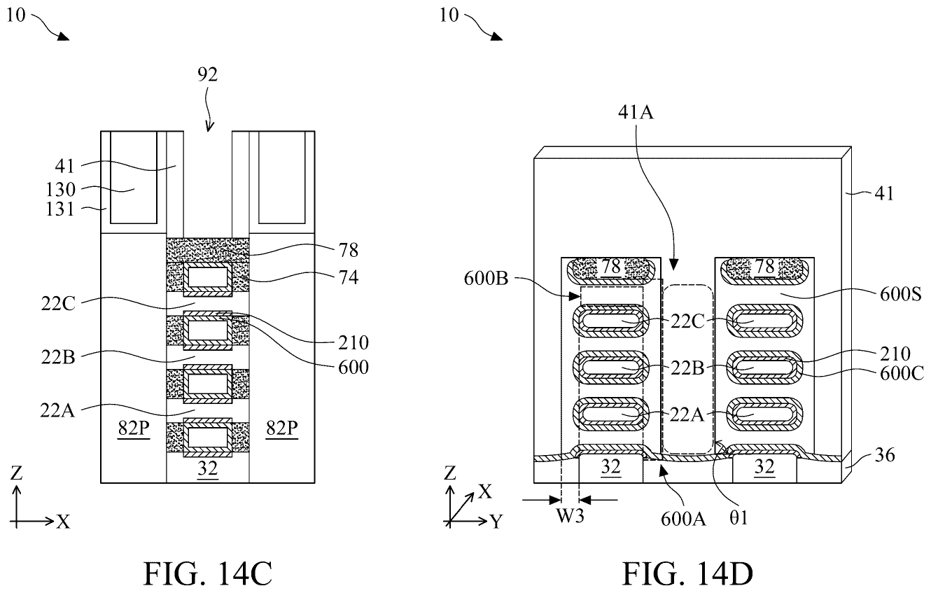

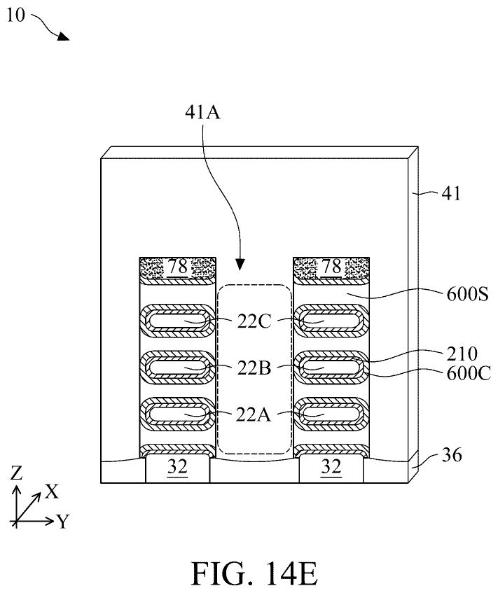

In FIGS. 14A-14E, the BARC layer 500′ is removed. Removal of the BARC layer 500′ may be by a suitable removal process, such as an ashing process or the like. With the BARC layer 500′ removed, the high-k dielectric layer 600 is exposed in the gate trenches 92. As depicted in FIG. 14B, the reduced high-k dielectric layer 600S can inherit the profile of the BARC layer 500′ described with reference to FIGS. 12A and 12B. As depicted in FIG. 14D, the reduced high-k dielectric layer 600S can inherit the profile of the BARC layer 500′ described with reference to FIGS. 12C and 12D. Namely, the reduced high-k dielectric layer 600S can include channel regions 600C on the channels 22 and inner spacer regions 600B that overlap inner spacers 74 between the channels 22 and between the channel 22A and the fin 32. The reduced high-k dielectric layer 600S can also include extension regions 600A laterally outside or adjacent the channels 22. The extension regions 600A can have non-uniform width in the Y-axis direction due to tapering (FIG. 14B) or can have substantially uniform or uniform width in the Y-axis direction due to the higher etching rate when the capping layer 710 is in place (FIG. 14D). The taper angles θ1 and distances W1, W2, W3 can be the same or substantially the same as those described with reference to FIGS. 12B and 12D. Namely, the taper angle θ1 can be in a range of about 60 degrees to about 85 degrees in FIG. 14B and in a range of about 85 degrees to 90 degrees in FIG. 14D. The distances W1, W2, W3 can be in a range of about 1.5 nm to about 20 nm. The reduced high-k dielectric layer 600S can expose a portion 41C of the gate spacer 41 that is below the GPT hard mask 78 and between the stack of nanostructures 22.

FIG. 14E depicts an embodiment in which the extension regions 600A are not present. In some embodiments, the BARC layer 500′ does not include the extension regions 500A, such that the excess material 600X includes the material of the high-k dielectric layer 600 immediately adjacent to the channel regions 600C on the channels 22. Namely, following the etching operation described with reference to FIG. 13A-13D, the reduced high-k dielectric layer 600S only includes the channel regions 600C and the inner spacer regions 600B that overlap the inner spacers 74 between the channels 22, the GPT hard mask 78 and the fin 32 and does not include the extension regions 600A.

In FIGS. 14A-14E, the reduced high-k dielectric layer 600S can cover a portion of surface area of the side surface of the gate spacer 41. In some embodiments, the portion can be measured as a percentage of the surface area of the gate spacer 41. For example, the portion of the gate spacer 41 covered by the reduced high-k dielectric layer 600S can be in a range of 0% (FIG. 14E) to about 50%. In some embodiments, the portion is in a range of about 5% to about 25%. In some embodiments, the profile of the etched BARC layer 500′ could be configured by tuning one or more of: the etching bias voltage (e.g., higher bias for sharper profile and vice versa) or (2) the etching gas of N2 and H₂ mixture plasma.

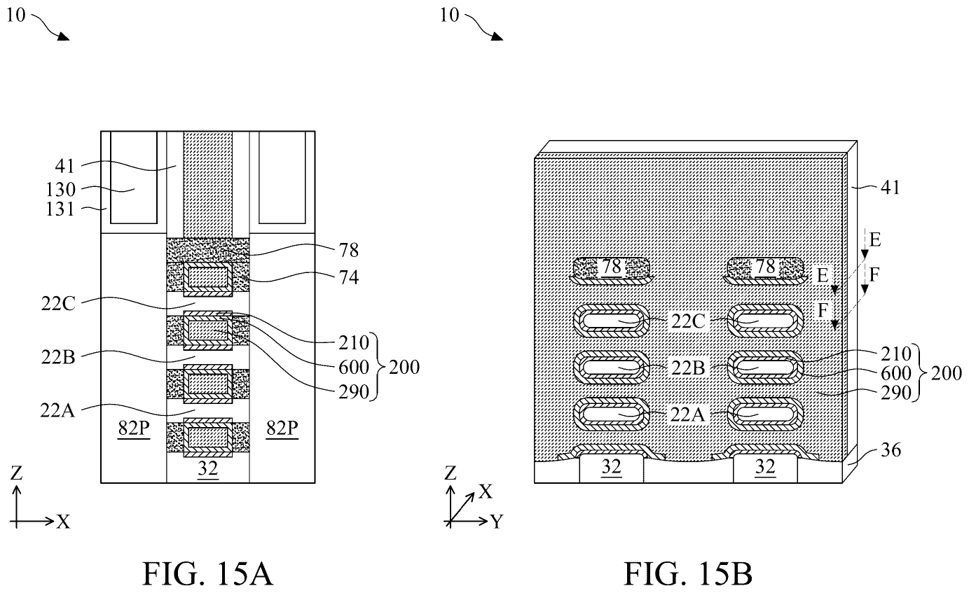

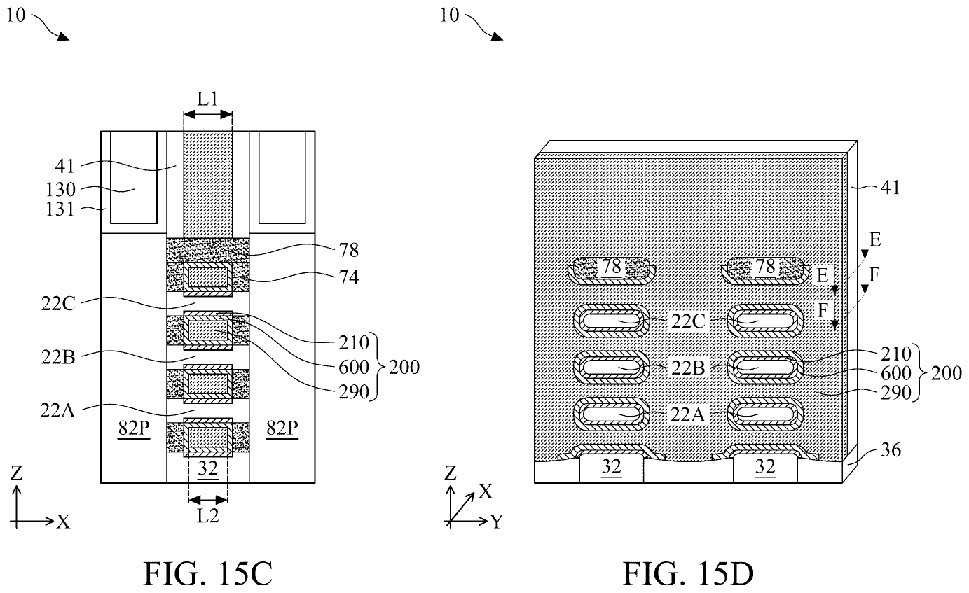

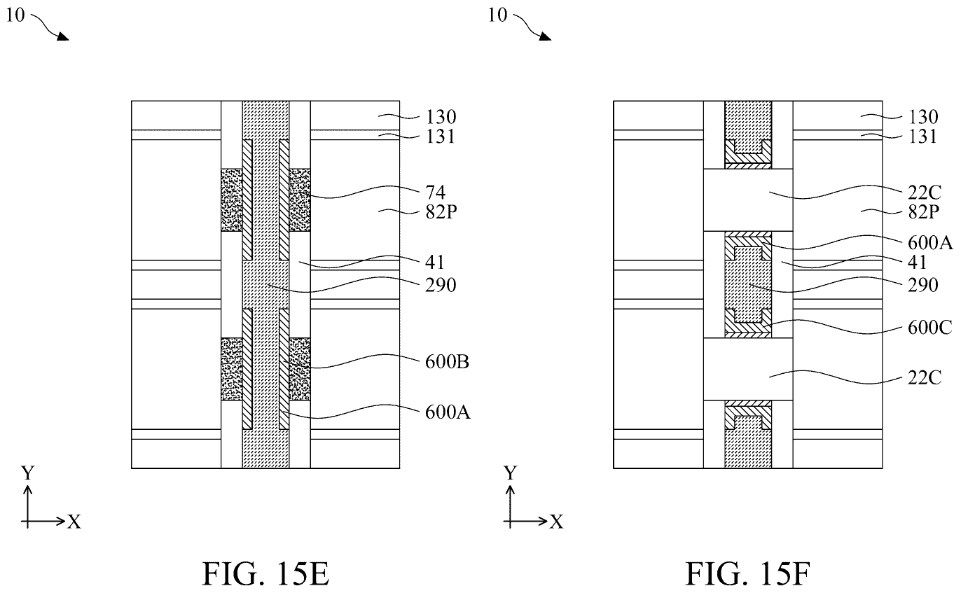

In FIGS. 15A-15D, the metal layer 290 of the gate structure 200 is formed on the reduced high-k dielectric layer 600S. Formation of the metal layer 290 may be similar in most respects to that described with reference to FIG. 17. Generally, the metal layer 290 can fill the gate trench 92 and can be positioned between and on the fin 32, the channels 22 and the GPT hard mask 78. The metal layer 290 can extend to the top of the gate trench 92, such as to have an upper surface that is coplanar with upper surfaces of the gate spacer 41, the ILD 130 and the ESL 131.

FIGS. 15E and 15F are plan views along the cross-sectional lines E-E and F-F of FIGS. 15B and 15D. As depicted in FIG. 15E, because the reduced high-k dielectric layer 600S is in place, the metal layer 290 may be in direct contact with exposed portions of the gate spacer 41, such as portions of the gate spacer 41 not covered by the inner spacer regions 600B and the extension regions 600A of the reduced high-k dielectric layer 600S. In some embodiments, as described with reference to FIG. 17, additional layers may be between the metal layer 290 and the gate spacer 41. For example, the second IL 240, the second work function layer 700, the work function tuning layer 900 the optional glue layer, or a combination thereof, can be present between the metal layer 290 and the gate spacer 41 without the reduced high-k dielectric layer 600S therebetween. For example, the second IL 240 may be in direct contact with the gate spacer 41. In another example, the second work function layer 700 may be in direct contact with the gate spacer 41. In yet another example, the work function tuning layer 900 may be in direct contact with the gate spacer 41.

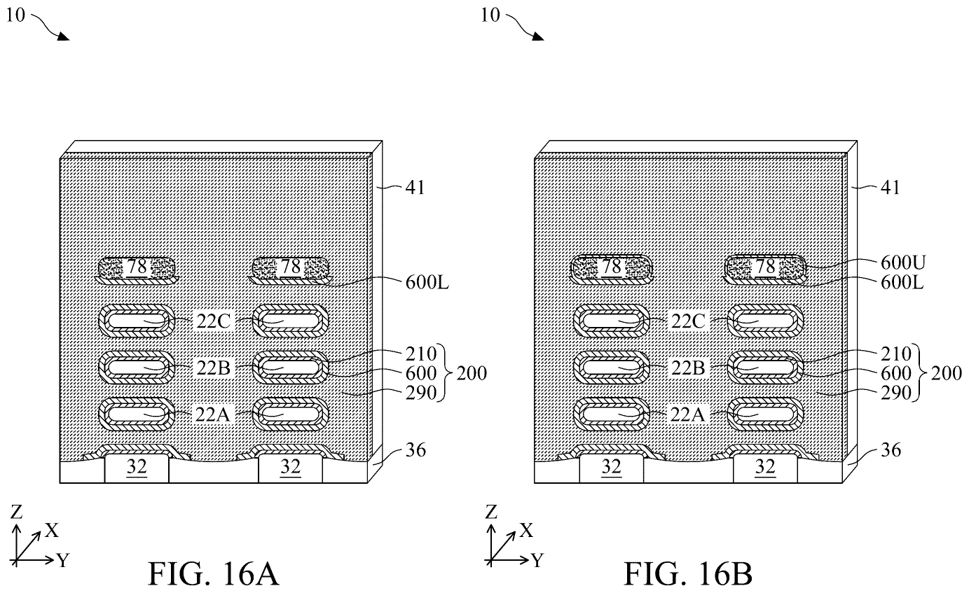

FIGS. 16A and 16B depict views of the device 10 in accordance with various embodiments. In some embodiments, as depicted in FIG. 16A and described previously with reference to FIGS. 13A-13D, a lower portion 600L of the reduced high-k dielectric layer 600S can be positioned on a bottom surface of the GPT hard mask 78 and may extend past corner regions of the GPT hard mask 78. For example, the lower portion 600L can extend past the corner regions of the GPT hard mask 78 by a distance that does not exceed thickness of the reduced hard mask layer 600S. As described with reference to FIG. 17, the high-k dielectric layer 600 and the reduced high-k dielectric layer 600S can have thickness in a range of about 0.5 nm to about 10 nm. In the embodiment depicted in FIG. 16A, the upper surface of the GPT hard mask 78 can be free of the reduced high-k dielectric layer 600S.

In FIG. 16B, the reduced high-k dielectric layer 600S can have an upper portion 600U and the lower portion 600L on the GPT hard mask 78. The lower portion 600L can be similar to the lower portion 600L described with reference to FIG. 16A. The upper portion 600U may be on the upper surface and optionally on side surfaces of the GPT hard mask 78. In some embodiments, the upper portion 600U can have thickness that is different than that of the lower portion 600L. In some embodiments, the lower portion 600L may have thickness that exceeds the thickness of the upper portion 600U by a value that is in a range of 0 nm (i.e., the same thickness) to about 2 nm. In some embodiments, thickness of the upper portion 600U is zero, which is the same as the embodiment depicted in FIG. 16A. In some embodiments, the thickness of the upper portion 600U exceeds zero and is less than about 8 nm. In the embodiment depicted in FIG. 16B, the GPT hard mask 78 may be entirely wrapped around by the upper and lower portions 600U, 600L of the reduced high-k dielectric layer 600S.

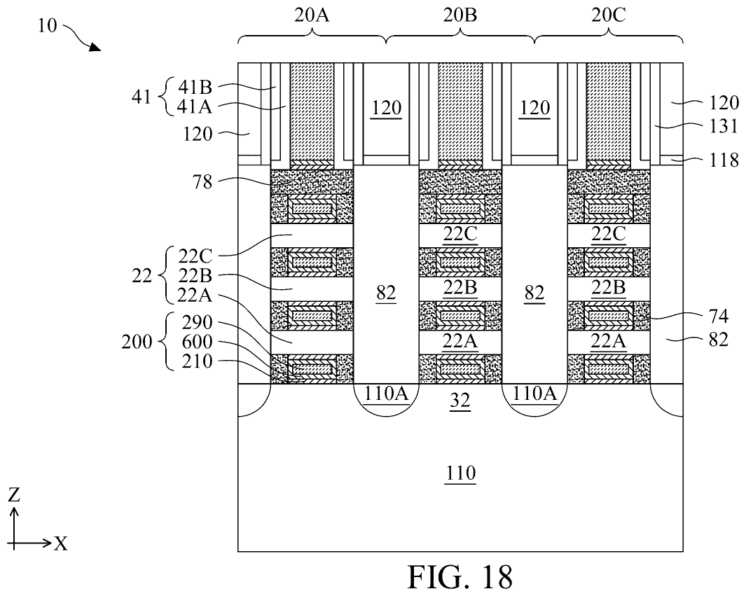

In FIG. 18, following formation of the gate structures 200, source/drain openings may be formed in the ILD 130 and source/drain contacts 120 may be formed in the source/drain openings. Silicide regions 118 and the source/drain contacts 120 are formed on source/drains 82, which can be the source/drain 82P, the source/drain 82N, or a combination thereof.

In some embodiments, the silicide layers 118 are formed prior to formation of the source/drain contacts 120. For example, an N-type or P-type metal layer may be formed as a conformal thin layer over exposed portions of the source/drain regions 82. The metal layer may be or include one or more of Ni, Co, Mn, W, Fe, Rh, Pd, Ru, Pt, Ir, Os or the like. In some embodiments, the metal layer is or includes one or more of Ti, Cr, Ta, Mo, Zr, Hf, Sc, Ys, Ho, Tb, Gd, Lu, Dy, Er, Yb or another suitable material. Following formation of the metal layer, the silicide layers 118 may be formed by annealing the device 10. Following the anneal, the silicide layers 118 may be or include one or more of NiSi, CoSi, MnSi, WSi, FeSi, RhSi, PdSi, RuSi, PtSi, IrSi, OsSi, TiSi, CrSi, TaSi, MoSi, ZrSi, HfSi, ScSi, YSi, HoSi, TbSi, GdSi, LuSi, DySi, ErSi, YbSi or the like. Silicide of the silicide layers 118 may diffuse into regions below the ESL 131. Thickness of the silicide layers 118 may be in a range of about 1 nm to about 10 nm. Below about 1 nm, contact resistance may be too high. Above about 10 nm, the silicide layers 118 may short with the channels 22C.

Following formation of the silicide layers 118, the source/drain contacts 120 are formed by filling the openings over the source/drain regions 82 with, for example, a liner layer and a fill layer. In some embodiments, the source/drain contacts 120 are formed by depositing a material that is or includes a conductive material such as Co, W, Ru, combinations thereof, or the like. In some embodiments, the source/drain contacts 120 are or include a Co-, W- or Ru-based compound or alloy including one or more elements, such as Zr, Sn, Ag, Cu, Au, Al, Ca, Be, Mg, Rh, Na, Ir, W, Mo, Zn, Ni, K, Co, Cd, Ru, In, Os, Si, Ge, Mn, combinations thereof, or the like. The source/drain contacts 120 land on the silicide layer 118 and are in contact with the ESL 131. Description of the device 10 and illustration thereof in many of the figures is given with reference to GAAFETs including vertical stacks of the nanostructures 22. In some embodiments, the silicide layers 118 and the source/drain contacts 120 are formed in and on source/drain regions 82 of FinFET devices.

Additional processing may be performed to finish fabrication of the nanostructure devices 20. For example, gate contacts (or gate vias) may be formed to electrically couple to the gate structures 200. An interconnect structure may then be formed over the source/drain contacts 120 and the gate contacts. The interconnect structure may include a plurality of dielectric layers (including, for example, a second ILD) surrounding metallic features, including conductive traces and conductive vias, which form electrical connection between devices on the substrate 110, such as the nanostructure devices 20A, 20B, 20C, as well as to IC devices external to the IC device 10.

Embodiments may provide advantages. By selectively removing portions of the gate dielectric 600 that are outside the channels 22 and the inner spacers 74 from the gate spacer 41, parasitic capacitance can be reduced without reducing beneficial on current ION. The selective removal can be accomplished by use of the gate top protection hard mask 78 and optionally the transition metal capping layer 710.

In accordance with at least one embodiment, a method includes forming a stack including alternating first semiconductor layers and second semiconductor layers on a substrate; forming a sacrificial gate structure on the stack; forming a gate spacer adjacent the sacrificial gate structure; releasing the first semiconductor layers by removing the second semiconductor layers; forming a gate dielectric on the first semiconductor layers and a side surface of the gate spacer; forming a reduced gate dielectric by removing a portion of the gate dielectric from the side surface of the gate spacer, the portion being laterally adjacent to the first semiconductor layers; and forming a gate metal layer on the reduced gate dielectric and exposed portions of the gate spacer.

In accordance with at least one embodiment, a method includes: forming a dielectric protective layer over a stack of alternating first nanostructures and second nanostructures; forming a gate spacer adjacent the first nanostructures; forming inner spacers between the first nanostructures; releasing the first nanostructures by removing the second nanostructures; forming a gate dielectric on the first nanostructures, the dielectric protective layer and the gate spacer; forming a capping layer on the dielectric protective layer, the capping layer having a width exceeding that of the dielectric protective layer; forming a reduced gate dielectric by removing a first portion of the gate dielectric from a side surface of the gate spacer, the portion having a width substantially equal to that of the dielectric protective layer; and forming a gate metal layer on the reduced gate dielectric and exposed portions of the gate spacer.

In accordance with at least one embodiment, a device includes: a stack of nanostructures; a first layer over and offset from the stack of nanostructures; an inner spacer between the first layer and the stack of nanostructures; and a gate structure wrapping around the stack of nanostructures. The gate structure includes a gate dielectric on the nanostructures and between the inner spacer and the nanostructures of the stack of nanostructures and a gate metal on the gate dielectric.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method, comprising:
forming a stack including alternating first semiconductor layers and second semiconductor layers on a substrate;
forming a sacrificial gate structure on the stack;
forming a gate spacer adjacent the sacrificial gate structure;
releasing the first semiconductor layers by removing the second semiconductor layers;
forming a gate dielectric on the first semiconductor layers and a side surface of the gate spacer;
forming a reduced gate dielectric by removing a portion of the gate dielectric from the side surface of the gate spacer, the portion being laterally adjacent to the first semiconductor layers; and
forming a gate metal layer on the reduced gate dielectric and exposed portions of the gate spacer.

2. The method of claim 1, further comprising:
prior to the forming a sacrificial gate structure, forming a dielectric protective layer over the stack.

3. The method of claim 2, wherein the forming the dielectric protective layer over the stack includes forming the dielectric protective layer that has a width that exceeds those of the first semiconductor layers.

4. The method of claim 2, wherein the forming the dielectric protective layer over the stack includes forming the dielectric protective layer that has width that is substantially same as that of at least one of the first semiconductor layers.

5. The method of claim 2, wherein the forming the gate dielectric includes forming the gate dielectric on the dielectric protective layer.

6. The method of claim 2, wherein the forming a reduced gate dielectric includes:
forming a mask layer on the gate dielectric, the mask layer covering the gate spacer;
forming a reduced mask layer by removing a portion of the mask layer by etching the mask layer using the dielectric protective layer as a first mask; and
etching the gate dielectric using the reduced mask layer as a second mask.

7. The method of claim 6, wherein the forming the reduced mask layer includes forming the reduced mask layer having a tapered profile that increases in width with proximity to the substrate.

8. A method, comprising:
forming a dielectric protective layer over a stack of alternating first nanostructures and second nanostructures;
forming a gate spacer adjacent the first nanostructures;
forming inner spacers between the first nanostructures;
releasing the first nanostructures by removing the second nanostructures;
forming a gate dielectric on the first nanostructures, the dielectric protective layer and the gate spacer;
forming a capping layer on the dielectric protective layer, the capping layer having a width exceeding that of the dielectric protective layer;
forming a reduced gate dielectric by removing a first portion of the gate dielectric from a side surface of the gate spacer, the portion having a width substantially equal to that of the dielectric protective layer; and
forming a gate metal layer on the reduced gate dielectric and exposed portions of the gate spacer.

9. The method of claim 8, wherein the forming the reduced gate dielectric includes:
forming a mask layer on the gate dielectric, the mask layer covering the gate spacer;
forming a reduced mask layer by removing a portion of the mask layer by etching the mask layer using the capping layer as a first mask; and
etching the gate dielectric using the reduced mask layer as a second mask.

10. The method of claim 8, wherein the forming the capping layer includes forming a transition metal nitride layer on the dielectric protective layer.

11. The method of claim 8, wherein the forming the dielectric protective layer includes:
forming a stack of first semiconductor layers and second semiconductor layers that is associated with the stack of alternating first nanostructures and second nanostructures;
forming a third semiconductor layer on the stack of first and second semiconductor layers;
forming a third nanostructure by forming a source or drain opening that extends through the stack of first and second semiconductor layers and the third semiconductor layer;
forming an opening by removing the third nanostructure; and
forming the dielectric protective layer in the opening.

12. The method of claim 11, wherein the forming the dielectric protective layer in the opening is conducted during the forming inner spacers between the first nanostructures.

13. The method of claim 11, wherein the forming the third semiconductor layer includes forming the third semiconductor layer having a germanium concentration that exceeds those of the first and second semiconductor layers.

14. The method of claim 8, wherein the forming the reduced gate dielectric includes removing a second portion of the gate dielectric from an upper surface of the dielectric protective layer.

15. A device, comprising:
a stack of nanostructures;
a first layer over and offset from the stack of nanostructures;
an inner spacer between the first layer and the stack of nanostructures; and
a gate structure wrapping around the stack of nanostructures, the gate structure including:
a gate dielectric on the nanostructures and between the inner spacer and the nanostructures of the stack of nanostructures; and
a gate metal on the gate dielectric.

16. The device of claim 15, wherein width of the first layer exceeds widths of the nanostructures of the stack of nanostructures.

17. The device of claim 15, wherein the gate dielectric on the inner spacer has a tapered profile below the first layer.

18. The device of claim 15, wherein the gate dielectric is adjacent to more than one side of the first layer.

19. The device of claim 18, wherein a first portion of the gate dielectric on a top surface of the first layer has thickness that is less than that of a second portion of the gate dielectric on a bottom surface of the first layer.

20. The device of claim 15, wherein a portion of the gate dielectric that is below the first layer has substantially uniform width between the first layer and a bottommost nanostructure of the stack of nanostructures.
